(19) United States
(12) Patent Application Publication
(10) Pub. No.: US 2012/0094220 A1
(43) Pub. Date: Apr. 19, 2012

(54) PHOTO MASK, PHOTOLITHOGRAPHY METHOD, SUBSTRATE PRODUCTION METHOD AND DISPLAY PANEL PRODUCTION METHOD

(75) Inventor: Kentaro Yoshiyasu, Osaka (JP)

(73) Assignee: SHARP KABUSHIKI KAISHA, Osaka (JP)

(21) Appl. No.: 13/378,769

(22) PCT Filed: May 21, 2010
(86) PCT No.: PCT/JP2010/058590

§ 371 Date: Dec. 16, 2011

(30) Foreign Application Priority Data
Jun. 20, 2009 (JP) 2009-147095

(51) Int. Cl. G03F 7/20; G03F 1/00

(52) U.S. Cl. 430/5; 430/325; 430/312; 430/7; 430/320

(57) ABSTRACT

Disclosed are an exposure mask, a photolithography method, a method of manufacturing a substrate and a display panel which can reduce the number of exposure masks required. The photolithography method uses an exposure mask 1a having a semi-transmissive pattern 12a, which blocks the light energy of the first wavelength band, and a semi-transmissive pattern 13a, which blocks the light energy of the second wavelength band. The photolithography method includes the steps of: forming a first photoresist material film 27; conducting an exposure process on the first photoresist material film 27 using the exposure mask 1a and the light energy of the first wavelength band; conducting a development process on the photoresist material film 27; forming a second photoresist film 28; conducting an exposure process on the second photoresist film 28 using the exposure mask 1a and the light energy of the second wavelength band; and conducting a development process on the second photoresist film 28.

### TECHNICAL FIELD

The present invention relates to an exposure mask (photo mask), a photolithography method, a method of manufacturing a substrate, and a method of manufacturing a display panel. More particularly, the present invention relates to an exposure mask used in a photolithography method, a photolithography method using the exposure mask, a method of manufacturing a substrate such as the substrate for a display panel, and a method of manufacturing a display panel.

### BACKGROUND ART

A general active matrix type liquid crystal display panel includes a TFT array substrate and an opposite substrate (as the opposite substrate, a color filter, for example, is applied). A liquid crystal display panel is configured such that the TFT array substrate and the opposite substrate are facing each other and bonded together with a prescribed small gap in between, and the gap is filled with liquid crystal.

The TFT array substrate used in an active matrix type liquid crystal display panel generally includes an active region (also referred to as “display region”) and a panel frame region bordering the active region.

In the active region, a prescribed number of pixel electrodes are arranged in a matrix, and switching elements such as thin film transistors that drive individual pixel electrodes are also arranged in a matrix. A thin film transistor generally includes a gate electrode, a source electrode and a drain electrode, and is configured such that the gate electrode and the drain electrode are formed in the same layer, and an insulating film (gate insulating film) is formed between the layer in which the source electrode is formed and the layer in which the gate electrode and the drain electrode are formed. Further, in the active region, gate wirings (also referred to as “gate bus lines” or “scan lines”), which send prescribed signals to the gate electrodes of respective thin film transistors, source wirings (also referred to as “source bus lines” or “data lines”), which send prescribed signals to the source electrodes of respective switching elements, and drain wirings, which electrically connect the drain electrodes of the switching elements to respective pixel electrodes, are provided. Also, reference wirings (also referred to as “Cs bus lines” or “holding capacitance wirings”) that form holding capacitances (also referred to as “storage capacitances” or “auxiliary capacitances”) with prescribed pixel electrodes may be provided.

In the panel frame region, a terminal region is provided for connection to a circuit substrate on which a driver IC or a driver LSI (commonly called “gate driver” or “source driver”) is mounted. In the terminal region, wiring electrode terminals are provided for connection to the terminals disposed on the circuit substrate. Also in the panel frame region, wirings are provided for electrically connecting the prescribed gate wirings, source wirings, and reference wirings disposed in the active region to the prescribed wiring electrode terminals disposed in the terminal region.

On the other hand, on the opposite substrate, a black matrix formed in a grid pattern and a colored layer of prescribed colors, which is formed in regions defined by the black matrix (that is, in individual areas inside the respective grids), are provided. Further, a common electrode is formed on the surface of the black matrix and the colored layer, and structures for controlling the liquid crystal alignment are provided at prescribed locations on the surface of the common electrode.

This way, prescribed wirings and prescribed elements are formed on the substrates used for a liquid crystal display panel.

Some of these prescribed wirings and prescribed elements are formed with the photolithography method. For example, gate wirings, source wirings, and reference wirings of the TFT array substrate, gate electrodes, source electrodes, and drain electrodes of the thin film transistor are formed with the photolithographic method. Specifically, in the case of the gate wirings, first, a conductive film layer, which will be the material of the gate wirings, is formed. Then, a photosensitive material film is formed on the surface of the conductive film. Further, an exposure process is conducted on the photosensitive material using an exposure mask (i.e., a photo mask), and a development process is conducted on this photosensitive material that was subjected to the exposure process. Once the development process is conducted, unnecessary portion of the photosensitive material is removed, and the photosensitive material is formed into the gate wiring pattern. The conductive film is then etched using the photosensitive material formed into the gate wiring pattern as the etching mask. This way, the conductive film is formed into the gate wiring pattern. Then, residual photosensitive material on the gate wiring surface is removed.

Some black matrices are formed from a photosensitive material. To form such a black matrix, first, a photosensitive material film is formed, and an exposure process is conducted on the photosensitive material film using an exposure mask. Then, development process is conducted on the photosensitive material that was subjected to the exposure process. This way, unnecessary portion of the photosensitive material film is removed, and a black matrix is formed.

As discussed above, an exposure mask is used in the exposure process of photosensitive materials. On the exposure mask, a light-transmitting pattern and a light-shielding pattern are formed according to the patterns of wirings and elements to be provided. That is, for an exposure mask to be used to form gate wirings, a light-transmitting pattern and a light-shielding pattern are made according to the pattern of the gate wirings, and for an exposure mask to be used to form a black matrix, a light-transmitting pattern and a light-shielding pattern are made according the pattern of the black matrix.

In general, therefore, the number of exposure masks required is the same as the number of the patterns to be made. The more patterns are made, the more exposure masks are needed. Because exposure masks are generally expensive, as the number of exposure masks increases, so does the manufacturing cost and facility cost, which leads to higher product prices. Also, a higher number of exposure masks requires increased amount of control and maintenance.

For this reason, a configuration employing an exposure mask having a light-shielding pattern made of a metal or the like for some portion and a light-transmitting pattern made of a wavelength selective material for the portion that the light-shielding pattern is not formed is proposed (see Patent Document 1). According to such a configuration, two types of elements can be formed with one exposure mask. The number of exposure masks therefore can be reduced.

However, in the photolithography method in which the exposure mask described in Patent Document 1 is used, out of the two types of elements, one of them is formed into the shape of the light-shielding pattern, and the other is formed into the shape of the combination of the light-shielding pattern and semi-transmissive pattern. Thus, because the shapes of the two types of elements are limited by the light-shielding patterns, the shapes of the two types of elements cannot be set without receiving any influence from each other. As a result, with the exposure mask described in Patent Document 1, the shapes of the elements to be made are limited.

### RELATED ART DOCUMENTS

### Patent Documents

Patent Document 1: Japanese Patent Application Laid-Open Publication No. S63-121054

### SUMMARY OF THE INVENTION

### Problems to be Solved by the Invention

In consideration of the situation described above, the present invention is aiming at providing an exposure mask (i.e., photo mask) that can form multiple types of patterns, a photolithography method that can form multiple types of patterns using a single exposure mask, a method of manufacturing a substrate in which the number of exposure masks can be reduced, and a method of manufacturing the display panel in which the number of exposure masks can be reduced; or providing an exposure mask that allows formation of multiple types of patterns without any interference between one pattern and other patterns (i.e., the shape of one pattern is not affected or limited by the shapes of other patterns), a photolithography method in which a multiple types of patterns can be formed with a single exposure mask, a method of manufacturing a substrate in which the number of exposure masks can be reduced, and a method of manufacturing a display panel in which the number of exposure masks can be reduced.

### Means for Solving the Problems

In order to solve the problems described above, an exposure mask of the present invention has a substantially transparent substrate and multiple types of semi-transmissive patterns formed on the substantially transparent substrate, each of which semi-transmissive patterns can block, among multiple types of light energy of different wavelength bands, the light energy of a prescribed wavelength band and can transmit the light energy of other wavelength bands, wherein the multiple types of semi-transmissive patterns block the light energy of respective wavelength bands that are different from one another.

The plurality of semi-transmissive patterns may be formed into different dimensions and shapes.

An exposure mask according to the present invention has a substantially transparent substrate and N types (N is an integer of at least 2) of semi-transmissive patterns formed on the substantially transparent substrate, each of which semi-transmissive patterns can block, among N types of light energy of different wavelength bands, the light energy of a prescribed wavelength band and can transmit light energy of other wavelength bands, wherein the N types of semi-transmissive patterns block light energy of respective wavelength bands that are different from one another.

The N types of semi-transmissive patterns may be formed into different dimensions and shapes.

An exposure mask according to the present invention has a substantially transparent substrate; a first semi-transmissive pattern that is formed on the substantially transparent substrate, that can block the light energy of a first wavelength band, and that can transmit the light energy of a second wavelength band that is different from the light energy of the first wavelength band; and a second semi-transmissive pattern that is formed on the substantially transparent substrate, that can block the light energy of the second wavelength band, and that can transmit the first wavelength band.

The exposure mask may be configured such that the first semi-transmissive pattern is formed on a surface of the substantially transparent substrate on one side of the direction of the thickness, and the second semi-transmissive pattern is formed on a surface of the substantially transparent substrate on the other side of the direction of the thickness.

An exposure mask according to the present invention is an exposure mask to be used to form multiple types of prescribed elements on a surface of a substrate as an object, and may be configured such that the first semi-transmissive pattern and the second semi-transmissive pattern are formed into dimensions and shapes corresponding to the dimensions and shapes of respective prescribed elements among the multiple types of prescribed elements.

For the substrate as an object, a TFT array substrate for the active matrix type liquid crystal display panel, which includes, as the prescribed elements, gate wirings, source wirings, a semiconductor film, reference wirings, thin film transistors, and an organic insulating film, may be employed. In this case, the first semi-transmissive pattern and the second semi-transmissive pattern may be formed into dimensions and shapes corresponding to dimensions and shapes of: the gate wirings and the gate electrodes of the thin film transistors; or the source wirings, the drain wirings, the source electrodes of the thin film transistors, and the drain wirings of the thin film transistors; or the organic insulating film; or the semiconductor film.

For the substrate as an object, a color filter for the active matrix type liquid crystal display panel including the black matrix and colored layers as the prescribed elements may be employed, and one of the first semi-transmissive pattern or the second semi-transmissive pattern may be formed into dimensions and a shape corresponding to the dimensions and the shape of the black matrix, and the other of the first semi-transmissive pattern or the second semi-transmissive pattern may be formed into dimensions and a shape corresponding to the dimensions and the shape of the colored layers.

A photolithography method according to the present invention is a photolithography method using the aforementioned exposure mask, and includes the steps of: forming a photoresist material film; conducting an exposure process on the photoresist material film using the exposure mask and light energy of a certain wavelength band; conducting a development process on the photoresist material film that went through the exposure process; forming another photoresist material film; conducting an exposure process on the another photoresist material film using the exposure mask and light energy of another wavelength band that is different from the wavelength band of the aforementioned light energy of a wavelength band; and conducting a development process on the aforementioned another photoresist material film that went through the exposure process.

For the aforementioned photoresist material film, a photoresist material film whose solubility in developer changes by being irradiated with the aforementioned light energy of the certain wavelength band may be employed. For the aforementioned another photoresist material film, a photoresist material film whose solubility in developer changes by being irradiated with the aforementioned light energy of the another wavelength band may be employed.

A photolithography method according to the present invention is a photolithography method using the aforementioned exposure mask, and includes the steps of: forming a photoresist material film; conducting an exposure process on the aforementioned photoresist material film using the exposure mask and using light energy of a prescribed wavelength band among the light energy of the N different wavelength bands; conducting a development process on the aforementioned photoresist material film that went through the exposure process; forming another photoresist material film; conducting an exposure process on the aforementioned another photoresist material film using the exposure mask and using light energy of another prescribed wavelength band among the light energy of the N different wavelength bands; and conducting a development process on the aforementioned another photoresist material film that went through the exposure process.

For the aforementioned photoresist material film, a photoresist material film whose solubility in developer changes by being irradiated with light energy of the prescribed wavelength band may be employed, and for the aforementioned another photoresist material film, a photoresist material film whose solubility in developer changes by being irradiated with light energy of the another prescribed wavelength band may be employed.

A photolithography method of the present invention is a photolithography method using the aforementioned exposure mask, and includes the steps of: forming a photoresist material film; conducting an exposure process on the photoresist material film using the exposure mask and light energy of the first wavelength band; conducting a development process on the photoresist material film that went through the exposure process; forming another photoresist material film; conducting an exposure process on the aforementioned another photoresist material film using the exposure mask and light energy of the second wavelength band; and conducting a development process on the aforementioned another photoresist material film that went through the exposure process.

For the aforementioned photoresist material film, a photoresist material film whose solubility in developer changes by being irradiated with light energy of the first wavelength band may be employed, and for the aforementioned another photoresist material film, a photoresist material film whose solubility in developer changes by being irradiated with light energy of the second wavelength band may be employed.

A photolithography method according to the present invention is a photolithography method using the aforementioned exposure mask, and includes the steps of: forming, on a substrate as an object, one of a film that is a material for the gate wirings and the gate electrodes of the thin film transistors, a film that is a material for the source wirings, the drain wirings, the source electrodes of the thin film transistors, and the drain wirings of the thin film transistors, a film that is a material for the organic insulating film, and a film that is a material of the semiconductor film; forming a photoresist material film on a surface of the film that was formed; conducting an exposure process on the aforementioned photoresist material film using the exposure mask and light energy of the first wavelength band; conducting a development process on the aforementioned photoresist material film that went through the exposure process; patterning the film that has been formed using the aforementioned photoresist material film that has been developed as a mask to form one of the gate wirings and the gate electrodes of the thin film transistors, the source wirings, the drain wirings, the source electrodes of the thin film transistors, and the drain wirings of the thin film transistors, the organic insulating film, and the semiconductor film; forming another photoresist material film; forming, on a surface of the substrate as an object, another one of a film that is a material for the gate wirings and the gate electrodes of the thin film transistors; a film that is a material for the source wirings, the drain wirings, the source electrodes of the thin film transistors, and the drain wirings of the thin film transistors, a film that is a material for the organic insulating film, and a film that is a material for the semiconductor film; conducting an exposure process on the aforementioned another photoresist material film that was formed using the exposure mask and light energy of the second wavelength band; conducting a development process on the aforementioned another photoresist material film that went through the exposure process; and patterning the film that was formed using the aforementioned another photoresist material film that was developed as a mask to form another one of the gate wirings and the gate electrodes of the thin film transistors, the source wirings, the drain wirings, the source electrodes of the thin film transistors, and the drain wirings of the thin film transistors, the organic insulating film, and the semiconductor film.

For the aforementioned photoresist material film, a photoresist material film whose solubility in developer changes by being irradiated with light energy of the first wavelength band may be employed, and for the aforementioned another photoresist material film, a photoresist material film whose solubility in developer changes by being irradiated with light energy of the second wavelength band may be employed.

A photolithography method according to the present invention is a photolithography method using the aforementioned exposure mask, and includes the steps of: forming a photoresist material film that is a material for the black matrix on a surface of the substrate as an object; conducting an exposure process on the photoresist material film that will be a material for the black matrix using the exposure mask and light energy of the first wavelength band; conducting a development process on the photoresist material film, which is the material for the black matrix, that went through the exposure process to form the black matrix; forming a photoresist material film that is a material for a colored layer of prescribed color; conducting an exposure process on the photoresist material film that is the material for the colored layer of prescribed color using the exposure mask and light energy of the second wavelength band; and conducting a development process on the photoresist material film, which is the material for the colored layers of prescribed colors, that went through the exposure process and will be a material for the colored layer of prescribed color to form the colored layer of prescribed color.

For the aforementioned photoresist material film, a photoresist material film whose solubility in developer changes by being irradiated with light energy of the first wavelength band may be employed, and for the aforementioned another photoresist material film, a photoresist material film whose solubility in developer changes by being irradiated with light energy of the second wavelength band may be employed.

The method of manufacturing a substrate according to the present invention includes a photolithography method according to the present invention.

The method of manufacturing a display panel according to the present invention includes a photolithography method according to the present invention.

### EFFECTS OF THE INVENTION

According to the present invention, multiple types of elements, which were conventionally formed with a plurality of exposure masks, can be formed with a single common exposure mask. As a result, the number of exposure masks required to manufacture a substrate for display panel or the like on which multiple types of elements will be formed can be reduced. Consequently, costs associated with the exposure mask (manufacturing cost, maintenance cost, and the like of the exposure mask) can be reduced, and therefore the overall manufacturing cost can be lowered. Also, because the number of exposure masks can be reduced, less storage space is needed.

Also, an exposure mask of the present invention is configured to include multiple types of semi-transmissive patterns that can block, among light energy of multiple different wavelength bands, the light energy of prescribed respective wavelength bands and can transmit the light energy of other wavelength bands. According to this configuration, when any one of the multiple types of semi-transmissive patterns is used in the exposure process, the light energy of a wavelength band that is blocked by this semi-transmissive pattern, but not blocked by other semi-transmissive patterns is used. In that case, only the image of above-mentioned semi-transmissive pattern is projected, and the images of any other semi-transmissive patterns are not projected. That is, when an exposure is conducted using the above-mentioned semi-transmissive pattern, other semi-transmissive patterns do not influence the exposure. Multiple types of semi-transmissive patterns therefore do not influence (i.e., do not interfere with) one another, and can be formed freely into any dimensions and shapes. As a result, dimensions and shapes of elements formed using a single exposure mask are not limited.

### BRIEF DESCRIPTION OF THE DRAWINGS

FIG. 1 schematically shows a substrate in Embodiment 1 of the present invention. FIG. 1(a) is an exterior perspective view and FIG. 1(b) is a cross-sectional view showing the cross-sectional structure.

FIG. 2 is an exterior perspective view schematically showing the structure of an exposure mask according to Embodiment 1 of the present invention. FIG. 2(a) is an exterior perspective view showing one surface (the surface on which the first semi-transmissive pattern is formed) of an exposure mask of Embodiment 1 of the present invention. FIG. 2(b) is an exterior perspective view showing the surface opposite to the surface shown in FIG. 2(a) (i.e., the surface on which the second semi-transmissive pattern is formed). FIG. 2(c) is a cross-sectional view schematically showing the cross sectional structure of the exposure mask of Embodiment 1 of the present invention.

FIG. 3 is a cross-sectional view schematically showing a prescribed step in the photolithography method according to an embodiment of the present invention (i.e., a prescribed step in the method for producing a first thin film pattern and a second thin film pattern). The figure illustrates the step of forming a first conductive film and a first photoresist material film on the surface of a substrate (baseboard).

FIG. 4 is a cross-sectional view schematically showing a prescribed step in the photolithography method according to an embodiment of the present invention (i.e., a prescribed step in the method for producing a first thin film pattern and a second thin film pattern). The figure illustrates the step of conducting an exposure process on the first photoresist material film using the exposure mask according to Embodiment 1 of the present invention.

FIG. 5 is a cross-sectional view schematically showing a prescribed step in the photolithography method according to an embodiment of the present invention (i.e., a prescribed step in the method for forming the first thin film pattern and the second thin film pattern). FIG. 5(a) illustrates the step of conducting a development process on the first photoresist material film, and FIG. 5(b) illustrates the step of patterning the first conductive film to form the first thin film pattern.

FIG. 6 is a cross-sectional view schematically showing a prescribed step in the photolithography method according to an embodiment of the present invention (i.e., a prescribed step in the method for forming the first thin film pattern and the second thin film pattern). FIG. 6(a) illustrates the step of removing the first photoresist material film, and FIG. 6(b) illustrates the step of forming an insulating film on a surface of the first thin film pattern.

FIG. 7 is a cross-sectional view schematically showing a prescribed step in the photolithography method according to an embodiment of the present invention (i.e., the prescribed step in the method for forming the first thin film pattern and the second thin film pattern). The figure illustrates the step of forming a second conductive film and a second photoresist material film on the surface of the insulating film.

FIG. 8 is a cross-sectional view schematically showing a prescribed step in the photolithography method according to an embodiment of the present invention (i.e., a prescribed step in the method for forming the first thin film pattern and the second thin film pattern). The figure illustrates the step of conducting an exposure process on the second photoresist material film using an exposure mask of Embodiment 1 of the present invention.

FIG. 9 is a cross-sectional view schematically showing a prescribed step in the photolithography method according to an embodiment of the present invention (i.e., a prescribed step in the method for forming the first thin film pattern and the second thin film pattern). FIG. 9(a) illustrates the step of conducting a development process on the second photoresist material film, and FIG. 9(b) illustrates the step of patterning the second conductive film to form the second thin film pattern.

FIG. 10 is a cross-sectional view schematically showing a prescribed step in the photolithography method according to an embodiment of the present invention (i.e., a prescribed step in the method for forming the first thin film pattern and the second thin film pattern). The figure illustrates the step of removing the second photoresist material film.

FIG. 11 is an exterior perspective view schematically showing the configuration of a substrate in Embodiment 2 of the present invention (TFT array substrate for an active matrix type liquid crystal display panel).

FIG. 12 is a plan view schematically showing the configuration of pixels formed on the substrate of Embodiment 2 of the present invention.

FIG. 13 schematically shows the configuration of an exposure mask of Embodiment 2 of the present invention. FIG. 13(a) is a cross-sectional view illustrating the cross-sectional structure, FIG. 13(b) is a plan view of the first semi-transmissive pattern, and FIG. 13(c) is a plan view of the second semi-transmissive pattern.

FIG. 14 schematically shows the configuration of an exposure mask according to Embodiment 3 of the present invention. FIG. 14(a) is a cross-sectional view illustrating the cross-sectional structure, FIG. 14(b) is a plan view of the first semi-transmissive pattern, and FIG. 13(c) is a plan view of the second semi-transmissive pattern.

FIG. 15 is a cross-sectional view schematically showing a prescribed step in the method of manufacturing a substrate of Embodiment 2 of the present invention. The figure illustrates the step of forming a first conductive film and the first photoresist material film on one surface of a transparent substrate.

FIG. 16 is a cross-sectional view schematically showing a prescribed step in the method of manufacturing a substrate of Embodiment 2 of the present invention. The figure schematically illustrates an exposure process of the photolithography method used in the step of forming gate wirings, reference wirings, and gate electrodes of thin film transistors.

FIG. 17 is a cross-sectional view schematically showing a prescribed step in the method of manufacturing the substrate of Embodiment 2 of the present invention. FIG. 17(a) schematically illustrates a development process of the photolithography method employed in the step of forming gate wirings, reference wirings, and gate electrodes of thin film transistors, and FIG. 17(b) schematically illustrates the step of patterning the first conductive film.

FIG. 18 is a cross-sectional view schematically showing a prescribed step in the method of manufacturing the substrate of Embodiment 2 of the present invention. FIG. 18(a) schematically illustrates the step of removing the first photoresist material, which is conducted after the development process of the photolithography method used in the step of forming gate wirings, reference wirings, and gate electrodes of thin film transistors, and FIG. 18(b) schematically illustrates the step of forming an insulating film.

FIG. 19 is a cross-sectional view schematically showing a prescribed step in the method of manufacturing the substrate of Embodiment 2 of the present invention. The figure schematically illustrates the step of forming a film that is a semiconductor film material and a second photoresist material film on one surface of the transparent substrate.

FIG. 20 is a cross-sectional view schematically showing a prescribed step in the method of manufacturing the substrate according to Embodiment 2 of the present invention. The figure schematically illustrates an exposure process of the photolithography method used in the step of forming a semiconductor film.

FIG. 21 is a cross-sectional view showing a prescribed step in the method of manufacturing the substrate of Embodiment 2 of the present invention. FIG. 21(a) schematically shows the development process of the photolithography method used in the step of forming a semiconductor film. FIG. 21(b) schematically shows the step of patterning the film that is a semiconductor film material.

FIG. 22 is a cross-sectional view schematically showing a prescribed step in the method of manufacturing the substrate of Embodiment 2 of the present invention. FIG. 22(a) schematically shows the step of removing the second photoresist material film, which is conducted after the development process of the photolithography method used in the step of forming the semiconductor film. FIG. 22(b) is a cross-sectional view schematically showing the step of forming a second conductive film and a third photoresist material film on one surface of the transparent substrate.

FIG. 23 is a cross-sectional view schematically showing a prescribed step in the method of manufacturing the substrate of Embodiment 2 of the present invention. The figure schematically illustrates an exposure process of the photolithography method used in the step of forming the source wirings, the drain wirings, and the source electrodes and drain electrodes of the thin film transistors.

FIG. 24 is a cross-sectional view schematically showing a prescribed step in the method of manufacturing the substrate of Embodiment 2 of the present invention. FIG. 24(a) schematically illustrates the development process in the photolithography method employed for the step of forming the source wirings, the drain wirings, the source electrodes and drain electrodes of the thin film transistors, and FIG. 24(b) schematically illustrates the step of patterning the second conductive film.

FIG. 25 is a cross-sectional view schematically showing a prescribed step in the method of manufacturing the substrate of Embodiment 2 of the present invention. FIG. 25(a) schematically illustrates the step of removing the third photoresist material film, which is conducted after the development process of the photolithography method used in the step of forming the source wirings, the drain wirings, and the source electrodes and drain electrodes of the thin film transistors, and FIG. 25(b) schematically illustrates the step of forming a passivation film.

FIG. 26 is a cross-sectional view schematically showing a prescribed step in the method of manufacturing the substrate of Embodiment 2 of the present invention. The figure schematically shows the step of forming a film that is an organic insulating film material.

FIG. 27 is a cross-sectional view schematically showing a prescribed step in the method of manufacturing the substrate of Embodiment 2 of the present invention. The figure schematically illustrates the step of conducting an exposure process on the film that is an organic insulating film material.

FIG. 28 is a cross-sectional view schematically showing a prescribed step in the method of manufacturing the substrate of Embodiment 2 of the present invention. FIG. 28(a) schematically illustrates the step of conducting a development process on the film, which is the organic insulating film material, and FIG. 28(b) is a cross-sectional view schematically illustrating the step of patterning the passivation film and the insulating film.

FIG. 29 is a cross-sectional view schematically showing a prescribed step in the method of manufacturing the substrate of Embodiment 2 of the present invention. The figure schematically illustrates the step of forming a pixel electrode.

FIG. 30 schematically shows the configuration of a substrate in Embodiment 3 of the present invention. FIG. 30(a) is a perspective view schematically showing the entire structure of the substrate of Embodiment 3 of the present invention. FIG. 30(b) is a plan view showing the configuration of one pixel formed on the substrate of Embodiment 3 of the present invention. FIG. 30(c) is a cross-sectional view taken along the line F-F of FIG. 30(b), and illustrates the cross-sectional configuration of a pixel.

FIG. 31 is an exterior perspective view schematically showing the configuration of an exposure mask of Embodiment 4 of the present invention. The figure is an exterior perspective view showing the surface on one side with respect to the direction of the thickness and illustrating the surface on which the first semi-transmissive pattern is formed.

FIG. 32 is an exterior perspective view schematically showing the configuration of the exposure mask of Embodiment 4 of the present invention. The figure is an exterior perspective view showing the surface on the other side with respect to the direction of the thickness (the surface on the opposite side from the surface shown in FIG. 31), and illustrates the surface on which the second semi-transmissive pattern is formed.

FIG. 33 is a cross-sectional view schematically showing a step of forming a black matrix. The figure illustrates the step of forming a BM resist on one side of the transparent substrate.

FIG. 34 is a cross-sectional view schematically showing the step of forming the black matrix. The figure illustrates the step of conducting an exposure process on the BM resist that has been formed.

FIG. 35 is a cross-sectional view schematically showing the step of forming the black matrix. FIG. 35(a) illustrates the step of conducting a development process on the BM resist that went through the exposure process. FIG. 35(b) illustrates the step of forming a colored photosensitive material film of a prescribed color on one surface of the transparent substrate.

FIG. 36 is a cross-sectional view schematically showing the step of forming a colored layer of respective color. The figure illustrates the step of conducting an exposure process on the colored photosensitive material film that has been formed.

FIG. 37 is a cross-sectional view schematically showing a step of forming the colored layer of respective color. The figure illustrates the step of conducting a development on the colored photosensitive material film that went through the exposure process.

FIG. 38 schematically shows the cross-sectional structure of a transparent substrate on which colored layers of all colors are formed (a half-completed substrate of Embodiment 3 of the present invention).

FIG. 39 is an exterior perspective view schematically showing the configuration of a display panel according to embodiments of the present invention.

### DETAILED DESCRIPTION OF EMBODIMENTS

Below, embodiments of the present invention are described in detail with reference to figures. The photoresist material used in the photolithography method is assumed positive type as an example. “Light energy” in the present invention includes infrared rays, ultraviolet rays, x-rays, gamma rays, and the like in addition to visible light.

In a photolithography method according to embodiments of the present invention, an exposure device that can selectively deliver light energy of N different wavelength bands (or a plurality of exposure devices that can deliver light energy of different wavelength bands; that is, N exposure devices are required if each exposure device is configured to deliver only light energy of a single wavelength band) and a single common exposure mask (i.e., photo mask) are used to form N different types of elements. In the description below, a configuration where N=2 is used as an example. That is, two types of elements can be formed using a single common exposure mask. In the step of exposure, two types of light energy of different wavelength bands (light energy of a first wavelength band and light energy of a second wavelength band) are used.

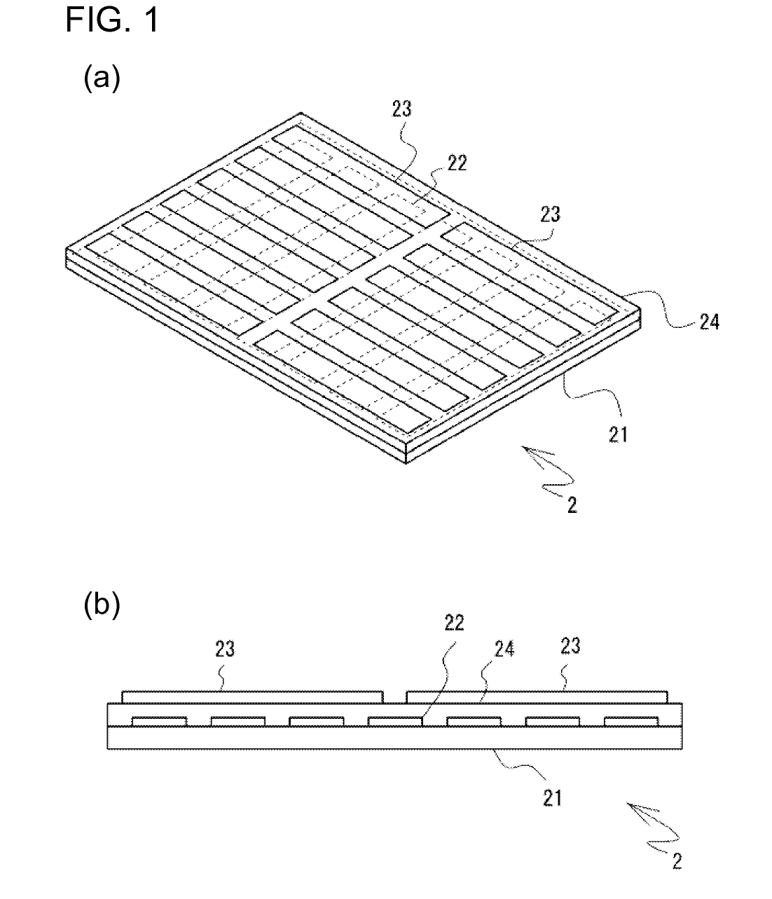

First, a substrate 2 of Embodiment 1 of the present invention is described. FIG. 1 schematically shows the substrate 2 of Embodiment 1 of the present invention. FIG. 1(a) is an exterior perspective view and FIG. 1(b) is a cross-sectional view showing the cross-sectional structure.

As shown in FIG. 1(a) and FIG. 1(b), the substrate 2 of Embodiment 1 of the present invention is configured to have two types of thin film patterns of different shapes (first thin film pattern 22 and second thin film pattern 23) on the surface of a baseboard 21. The first thin film pattern 22 and the second thin film pattern 23 are formed in separate layers sandwiching an insulating film 24. That is, the substrate 2 of Embodiment 1 of the present invention is configured such that the first thin film pattern 22, the insulating film 24, and the second thin film pattern 23 are layered. A photolithography method according to an embodiment of the present invention is employed in the process of forming the first thin film pattern 22 and the second thin film pattern 23.

The shapes and the number of the strips of the first thin film pattern 22 and of the second thin film pattern 23 shown in FIG. 1 are schematically illustrated to assist with the description, and do not necessarily reflect the actual shapes of the first thin film pattern 22 and the second thin film pattern 23.

The first thin film pattern 22 and the second thin film pattern 23 are formed with a photolithography method according to an embodiment of the present invention. That is, the first thin film pattern 22 and the second thin film pattern 23, which have different shapes, are formed using a common exposure mask (an exposure mask 1a of Embodiment 1 of the present invention) and using an exposure device that can selectively deliver the light energy of a first wavelength band and the light energy of a second wavelength band (or two exposure devices: one that can deliver the light energy of the first wavelength band and the other that can deliver the light energy of the second wavelength band). The first wavelength band and the second wavelength band are different wavelength bands of the light energy.

Next, the exposure mask (i.e., exposure mask 1a of Embodiment 1 of the present invention) used to form the first thin film pattern 22 and the second thin film pattern 23 of the substrate 2 of Embodiment 1 of the present invention is described.

The exposure mask 1a of Embodiment 1 of the present invention may be either a positive type exposure mask or a negative exposure mask. Here, as an example, it is assumed that the exposure mask 1a of Embodiment 1 of the present invention is a positive type exposure mask, and a positive type photoresist material is used in the photolithography method in the embodiment of the present invention.

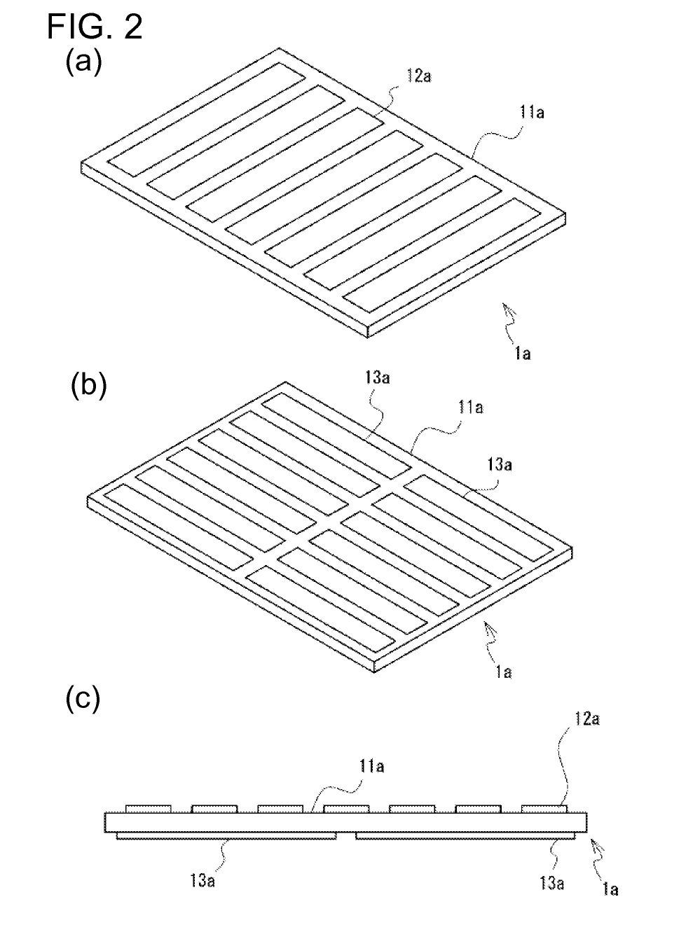

FIG. 2 schematically shows the structure of the exposure mask 1a of Embodiment 1 of the present invention. Specifically, FIG. 2(a) is an exterior perspective view showing one surface of the exposure mask 1a of Embodiment 1 of the present invention. The figure illustrates the surface on which first semi-transmissive pattern 12a is formed. FIG. 2(b) is an exterior perspective view showing the surface opposite to the surface shown in FIG. 2(a). The figure illustrates the surface on which the second semi-transmissive pattern 13a is formed. FIG. 2(c) is a cross-sectional view schematically showing the cross-sectional structure of the exposure mask 1a of Embodiment 1 of the present invention.

As shown in FIG. 2, the exposure mask 1a of Embodiment 1 of the present invention includes a transparent substrate 11a made of glass or the like (i.e., a substrate that can transmit both the light energy of the first wavelength band and the light energy of the second wavelength band, which are delivered by an exposure device). The transparent substrate 11a is configured such that first semi-transmissive pattern 12a for forming the first thin film pattern 22 is disposed on the surface on one side with respect to the direction of the thickness, and the second semi-transmissive pattern 13a for forming second thin film pattern 23 is formed on the surface on the other side.

Alternatively, the transparent substrate 11a may be configured such that both the first semi-transmissive pattern 12a and the second semi-transmissive pattern 13a may be formed on the surface on one side with respect to the direction of the thickness. In this case, the first semi-transmissive pattern 12a and the second semi-transmissive pattern 13a may be formed as a layered structure.

The first semi-transmissive pattern 12a can block the light energy of the first wavelength band (by reflection or absorption) and can transmit the light energy of the second wavelength band. The second semi-transmissive pattern 13a can block the light energy of the second wavelength band and can transmit the light energy of the first wavelength band.

For example, if light energy of a short wavelength band (i.e., light energy of a blue wavelength band) is used as the light energy of the first wavelength band, and if light energy of a long wavelength band (i.e., light energy of a red wavelength band) is used as the light energy of the second wavelength band, a configuration where the first semi-transmissive pattern 12a is made of a material containing a blue pigment, and the second semi-transmissive pattern 13a is made of a material containing a red pigment can be employed. With this configuration, the light energy of the short wavelength band cannot pass through the first semi-transmissive pattern 12a, because it reacts with the blue pigment and is absorbed or reflected. It, however, does not react with the red pigment and therefore is not absorbed or reflected. Consequently, the light energy of the short wavelength band can pass through the second semi-transmissive pattern 13a. The light energy of a long wavelength band cannot pass through the second semi-transmissive pattern 13a, because it reacts with the red pigment and is absorbed or reflected. It, however, does not react with the blue pigment and therefore is not absorbed or reflected. Consequently, the light energy of the long wavelength band can pass through the first semi-transmissive pattern 12a.

As the blue pigment, fine particles made of a metal such as Cu (copper) or Co (cobalt), for example, can be used. As the red pigment, fine particles made of a metal such as Au (gold), for example, can be used. Further, as the green pigment, fine particles made of a metal such as Cr (chrome) or Fe (iron), for example, can be used. As the yellow pigment, fine particles made of a metal such as Ag (silver) or Ni (nickel), for example, can be used. This way, fine particles made of certain metals or the like can be used as pigments of prescribed colors to block the light energy of respective wavelength bands.

The first semi-transmissive pattern 12a is formed into a shape and dimensions corresponding to the shape and dimensions of the first thin film pattern 22 formed on the substrate 2 of Embodiment 1 of the present invention. It is formed into approximately the same shape and dimensions as the first thin film pattern 22, for example. The second semi-transmissive pattern 13a is formed into a shape and dimensions corresponding to the shape and dimensions of the second thin film pattern 23 of Embodiment 1 of the present invention. It is formed into approximately the same shape and dimensions of the second thin film pattern 23.

When the exposure mask 1a of Embodiment 1 of the present invention is observed from the direction of the thickness, the first semi-transmissive pattern 12a and the second semi-transmissive pattern 13a may overlap with one another. That is, the positions and shapes of the first semi-transmissive pattern 12a and those of the second semi-transmissive pattern 13a do not restrict one another.

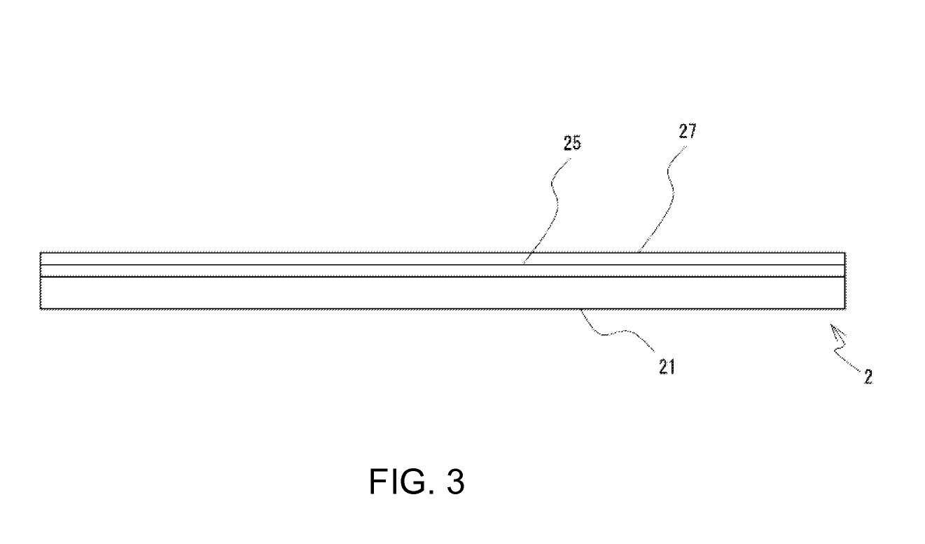

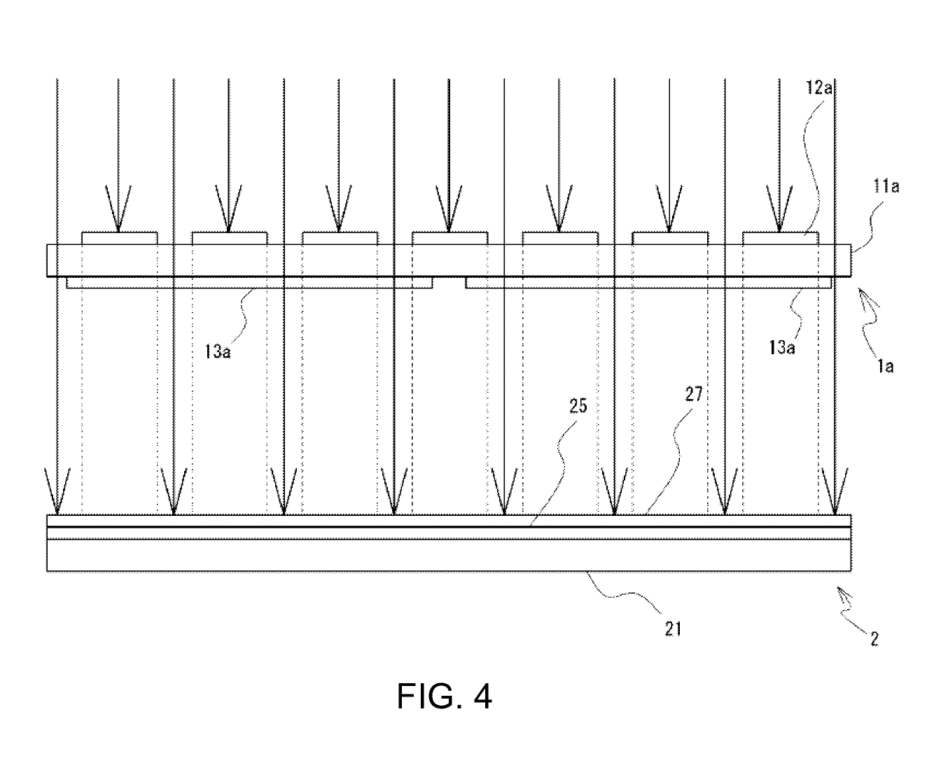

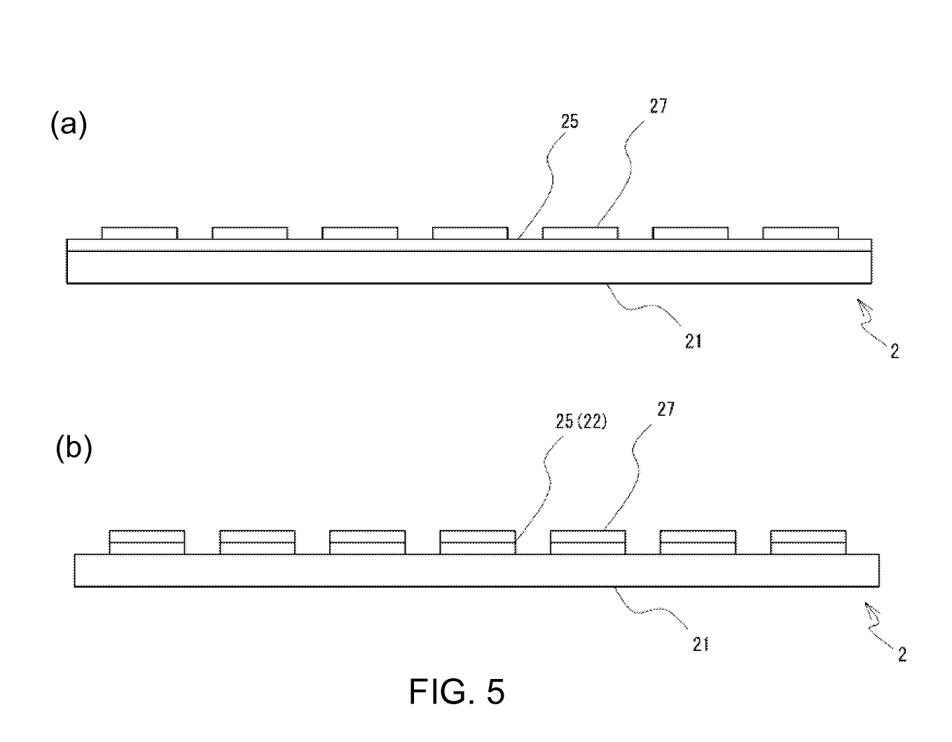

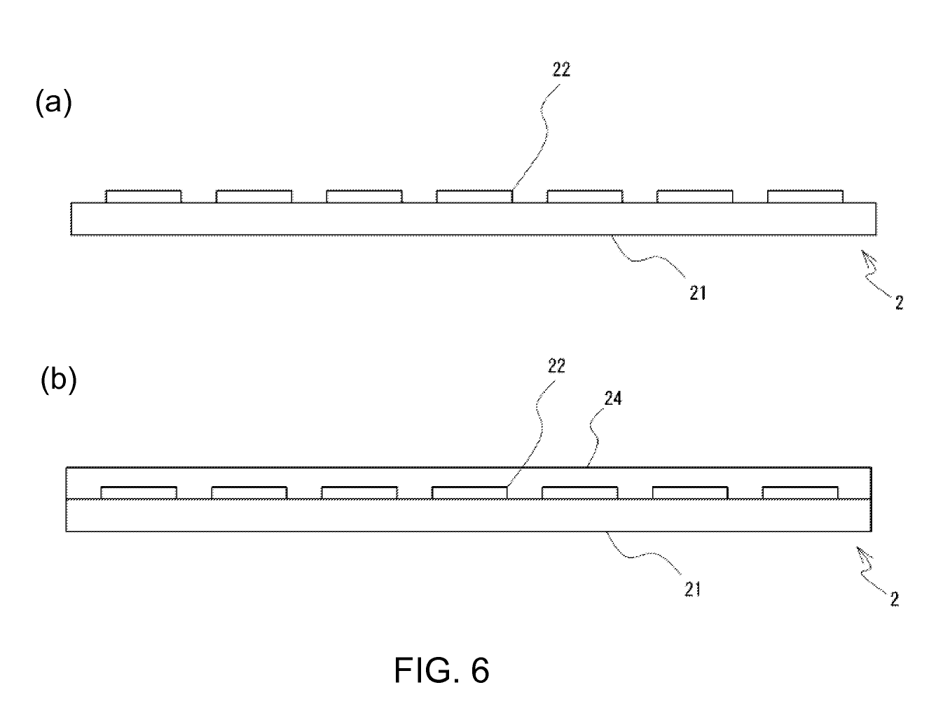

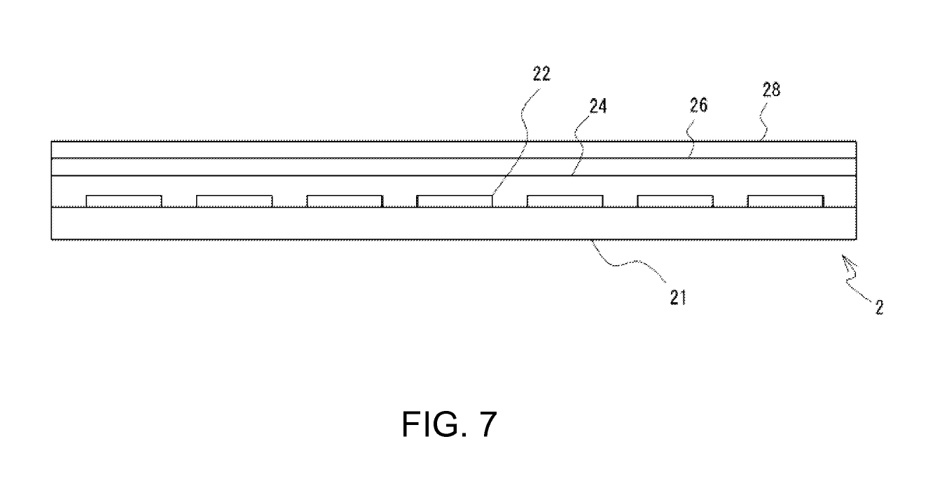

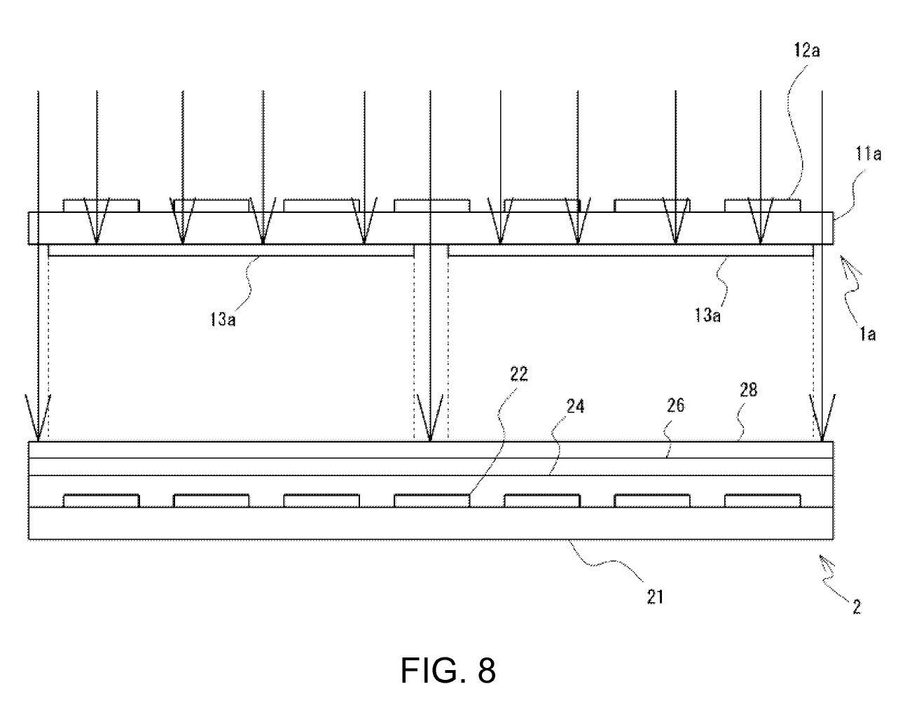

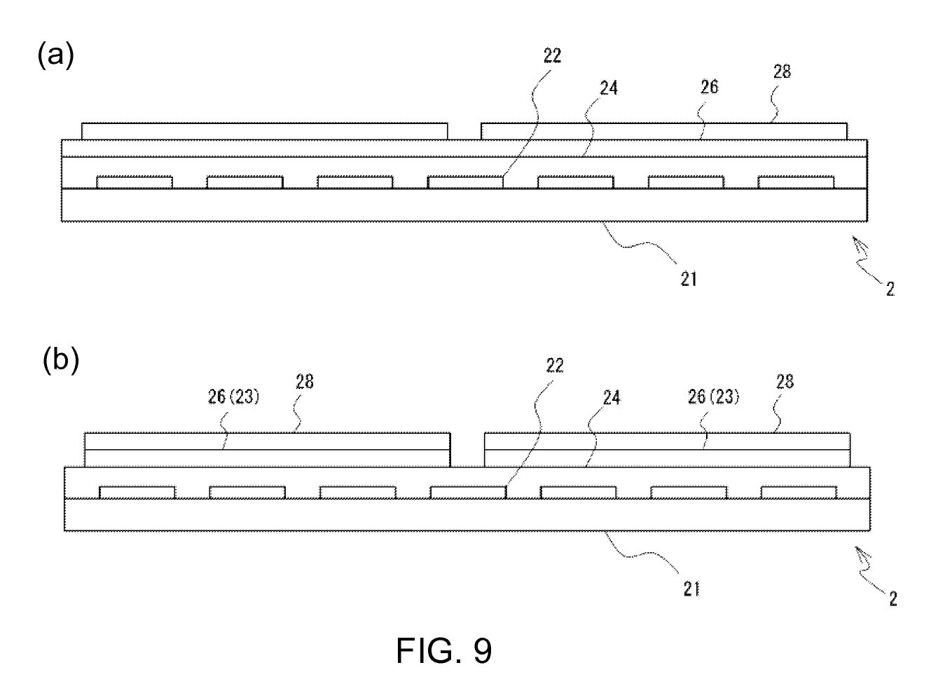

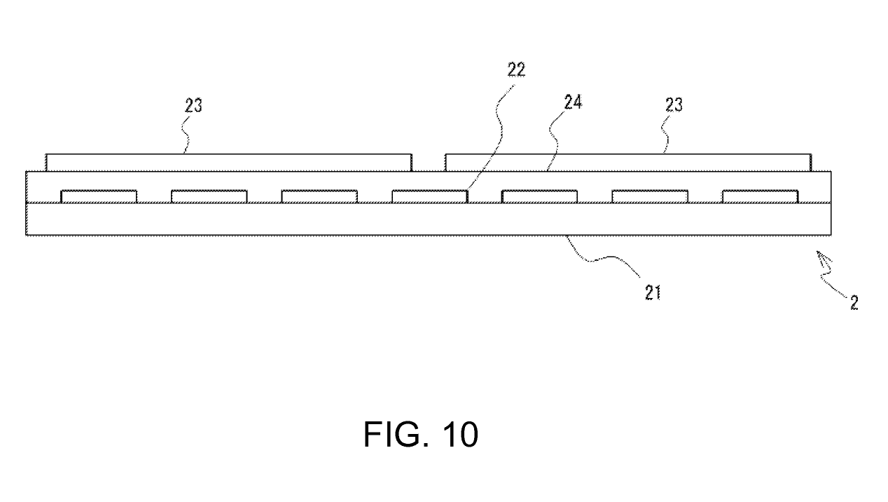

Next, the method of forming the first thin film pattern 22 and the second thin film pattern 23 with a photolithography method according to an embodiment of the present invention is described. FIG. 3 to FIG. 10 are cross-sectional views schematically showing the steps in the photolithography method according to an embodiment of the present invention (i.e., steps of forming the first thin film pattern 22 and the second thin film pattern 23). Specifically, FIG. 3 shows the step of forming a first conductive film 25 and a first photoresist material film 27 on the surface of the substrate 2 (baseboard 21) of Embodiment 1 of the present invention. FIG. 4 shows the step of conducting an exposure process on the first photoresist material film 27 using the exposure mask 1a of Embodiment 1 of the present invention. FIG. 5(a) shows the step of conducting a development process on the first photoresist material film 27. FIG. 5(b) shows the step of patterning the first conductive film 25 and forming the first thin film pattern 22. FIG. 6(a) shows the step of removing the first photoresist material film 27. FIG. 6(b) shows the step of forming an insulating film 24 on the surface of the first thin film pattern 22. FIG. 7 shows the step of forming a second conductive film 26 and a second photoresist material film 28 on the surface of the insulating film 24. FIG. 8 shows the step of conducting an exposure process on the second photoresist material film 28 using the exposure mask 1a of Embodiment 1 of the present invention. FIG. 9(a) shows the step of conducting a development process on the second photoresist material film 28. FIG. 9(b) shows the step of patterning the second conductive film 26 and forming the second thin film pattern 23. FIG. 10 shows the step of removing the second photoresist material film 28.

FIG. 3 shows the step of forming the first conductive film 25 and the first photoresist material film 27 on the surface of the substrate 2 (baseboard 21) of Embodiment 1 of the present invention. First, on the surface of the substrate 2 (baseboard 21) of Embodiment 1 of the present invention, the first conductive film 25 is formed, and the first photoresist material film 27 is formed to cover the first conductive film 25. There is no special limitation in the material of the first conductive film 25. To form the first conductive film 25, various known sputtering methods or the like can be used. On the surface of the first conductive film 25 which is now formed, the first photoresist material film 27 is formed to cover the first conductive film 25.

For the first photoresist material film 27, a photoresist material whose solubility in developer changes by being irradiated with light energy of a first wavelength band is used.

If the first photoresist material film 27 is made of a positive type photoresist material, by being irradiated with the light energy of the first wavelength band in the exposure process, the portion exposed to the light energy is removed in the development process. There is no special limitation in the method of forming the first photoresist material film 27. For example, a solution that will be a material for the first photoresist material film 27 can be applied on the surface of the first conductive film 25 using a spin coater, and then be cured.

Next, as shown in FIG. 4, an exposure process is conducted using the exposure mask 1a of Embodiment 1 of the present invention and an exposure device (not shown). FIG. 4 shows the step of conducting the exposure process on the first photoresist material film 27 using the exposure mask 1a of Embodiment 1 of the present invention. The arrows in the figure schematically indicate the light energy. In this exposure process, the exposure device delivers the light energy of the first wavelength band. That is, on the surface of the first photoresist material film 27, the exposure mask 1a of Embodiment 1 of the present invention is placed, and through the exposure mask 1a of Embodiment 1 of the present invention, the first photoresist material film 27 is irradiated with the light energy of the first wavelength band.

When the exposure device delivers the light energy of the first wavelength band, a portion of the light energy of the first wavelength band is blocked by first semi-transmissive pattern 12a of the exposure mask 1a of Embodiment 1 of the present invention (through absorption or reflection, for example), and the remaining light energy passes through the exposure mask 1a of Embodiment 1 of the present invention. Because the light energy of the first wavelength band can pass through the second semi-transmissive pattern 13a, the second semi-transmissive pattern 13a does not become a barrier to the passage of the light energy of the first wavelength band through the exposure mask 1a of Embodiment 1 of the present invention. As a result, the portion of the first photoresist material film 27 over which the first semi-transmissive pattern 12a is projected is not irradiated with the light energy of the first wavelength band, and the remaining portion is irradiated with the light energy of the first wavelength band regardless of the presence of the second semi-transmissive pattern 13a.

Next, as shown in FIG. 5(a), the first photoresist material film 27, which went through the exposure process, is developed. FIG. 5(a) shows the step of conducting a development process on the first photoresist material film 27. In the development process, if the first photoresist material film 27 is made of a positive type photoresist material, the portion irradiated with the light energy of the first wavelength band is removed, and the portion that was not irradiated (i.e., the portion over which the first semi-transmissive pattern 12a was projected) is not removed and remains on the surface of the first conductive film 25. As a result, the first photoresist material film 27 formed into the dimensions and shape of the first thin film pattern 22 remains on the surface of the first conductive film 25.

Next, as shown in FIG. 5(b), the first conductive film 25 is patterned to form the first thin film pattern 22. FIG. 5(b) shows the step of patterning the first conductive film 25 to form the first thin film pattern 22. For the patterning of the first conductive film 25, etching can be conducted using the first photoresist material film 27 as the etching mask. For this etching, various known etching techniques such as the wet etching using a prescribed etchant or the dry etching using a prescribed reactive gas can be employed. Then, as shown in FIG. 6(a), the first photoresist material film 27 is removed. FIG. 6(a) shows the step of removing the first photoresist material film 27.

Next, as shown in FIG. 6(b), an insulating film 24 is formed over the surface of the substrate 2 of Embodiment 1 of the present invention (baseboard 21), which went through the above-mentioned steps. FIG. 6(b) shows the step of forming the insulating film 24 over the surface of the first thin film pattern 22. Once the insulating film 24 is formed, the first thin film pattern 22 is covered with the insulating film 24.

Next, as shown in FIG. 7, over the surface of the insulating film 24, a second conductive film 26 and a second photoresist material film 28 are formed. FIG. 7 shows the step of forming a second conductive film 26 and a second photoresist material film 28 over the surface of the insulating film 24. There is no special limitation to the materials for the second conductive film 26. For the formation of the second conductive film 26, known methods such as various sputtering techniques can be used. Next, on the surface of the second conductive film 26 which is now formed, the second photoresist material film 28 is formed.

For the second photoresist material film 28, a photoresist material whose solubility in developer changes by being irradiated with light energy of the second wavelength band is used.

If the second photoresist material film 28 is made of a positive type photoresist material, by being irradiated with the light energy of the second wavelength band in the exposure process, the portion exposed to the light energy is removed in the development process. There is no special limitation to the method of forming the second photoresist material film 28. For example, a solution that will be a material for the second photoresist material film 28 can be applied on the surface of the second conductive film 26 using a spin coater, and then be cured.

Next, as shown in FIG. 8, an exposure process is conducted on the second photoresist material film 28 using the exposure mask 1a of Embodiment 1 of the present invention and an exposure device. FIG. 8 schematically shows the step of conducting the exposure process on the second photoresist material film 28 using the exposure mask 1a of Embodiment 1 of the present invention. The arrows in the figure schematically indicate the light energy. In this exposure process, the exposure device (not shown) delivers the light energy of the second wavelength band. That is, on the surface of the second photoresist material film 28, the exposure mask 1a of Embodiment 1 of the present invention is placed, and through the exposure mask 1a of Embodiment 1 of the present invention, the second photoresist material film 28 is irradiated with the light energy of the second wavelength band.

When the exposure device delivers the light energy of the second wavelength band, a portion of the light energy of the second wavelength band is blocked by second semi-transmissive patterns 13a of the exposure mask 1a of Embodiment 1 of the present invention, and the remaining light energy passes through the exposure mask 1a of Embodiment 1 of the present invention. Because the light energy of the second wavelength band can pass through the first semi-transmissive pattern 12a, the first semi-transmissive pattern 12a does not become a barrier to the passage of the light energy of the second wavelength band through the exposure mask 1a of Embodiment 1 of the present invention. As a result, the portion of the second photoresist material film 28 over which the second semi-transmissive pattern 13a is projected is not irradiated with the light energy of the second wavelength band, and the remaining portion is irradiated with the light energy of the second wavelength band regardless of the presence of the first semi-transmissive pattern 12a.

Next, as shown in FIG. 9(a), the second photoresist material film 28, which went through the exposure process, is developed. FIG. 9(a) shows the step of conducting a development process on the second photoresist material film 28. In the development process, In the development process, if the second photoresist material film 28 is made of a positive photoresist material, the portion irradiated with the light energy of the second wavelength band is removed, and the portion that was not irradiated (i.e., the portion over which the second semi-transmissive pattern 13a was projected) is preserved on the surface of the second conductive film 26. As a result, the second photoresist material film 28 formed into the dimensions and shape of the second thin film pattern 23 is preserved on the surface of the second conductive film 26.

Next, as shown in FIG. 9(b), the second conductive film 26 is patterned to form second thin film pattern 23. FIG. 9(b) shows the step of patterning the second conductive film 26 to form the second thin film pattern 23. For the patterning of the second conductive film 26, etching is conducted using the second photoresist material film 28 as the etching mask. For this etching, various known etching techniques such as the wet etching using a prescribed etchant or the dry etching using a prescribed reactive gas can be employed.

Then, as shown in FIG. 10, the second photoresist material film 28 is removed. FIG. 10 shows the step of removing the second photoresist material film 28.

After going through the steps described above, two different types of thin film patterns (the first thin film pattern 22 and the second thin film pattern 23) are formed on the surface of the baseboard 21. With such a configuration, separate exposure masks are not required in the steps of forming the first thin film pattern 22 and the second thin film pattern 23. With a single exposure mask (the exposure mask 1a of Embodiment 1 of the present invention), both the first thin film pattern 22 and the second thin film pattern 23 are formed. Also, with the exposure mask 1a of Embodiment 1 of the present invention and the photolithography method according to the embodiment of the present invention, the shapes of the first thin film pattern 22 and the second thin film pattern 23 do not interfere with each other. Accordingly, no limitation is imposed on the shapes of the first thin film pattern 22 and the second thin film pattern 23.

That is, with the exposure mask 1a and the photolithography method of Embodiment 1 of the present invention, multiple types (two types in embodiments of the present invention) of elements, which were conventionally formed with a plurality of exposure masks, can be formed with a single exposure mask. The number of exposure masks required to form multiple types of elements therefore can be reduced. Consequently, costs associated with the exposure mask (manufacturing cost, maintenance cost, and the like of the exposure mask) can be reduced, and therefore, the overall manufacturing cost can be lowered. Also, because the number of exposure masks can be reduced, less storage space is needed.

Also, the exposure mask 1a of Embodiment 1 of the present invention is configured to include multiple types of semi-transmissive patterns (i.e., the first semi-transmissive pattern 12a and the second semi-transmissive pattern 13a) that can block, among multiple types of light energy of different wavelength bands (i.e., the light energy of the first wavelength band and the light energy of the second wavelength band), the light energy of a prescribed wavelength band and can transmit the light energy of other wavelength bands. According to this configuration, when any one of the multiple types of semi-transmissive patterns is used in the exposure process, the light energy of a wavelength that is blocked by this semi-transmissive pattern, but not blocked by other semi-transmissive patterns is used. In that case, only the image of above-mentioned semi-transmissive pattern is projected, and the images of other semi-transmissive patterns are not projected. That is, when an exposure is conducted using the above-mentioned semi-transmissive pattern, the other semi-transmissive pattern does not influence the exposure. Multiple types of semi-transmissive patterns therefore do not influence (i.e., do not interfere with) one another, and can be formed freely into any dimensions and shapes. As a result, dimensions and shapes of elements formed using a single exposure mask are not limited.

In the above description, the exposure mask 1a of Embodiment 1 of the present invention is configured to include two types of semi-transmissive patterns (i.e., the first semi-transmissive pattern 12a and the second semi-transmissive pattern 13a). However, the number of semi-transmissive patterns is not limited. The exposure mask 1a may be configured to include three or more types of semi-transmissive patterns (N is an integer of more than 3), for example. In this case, the configuration can be such that each of the semi-transmissive patterns blocks the light energy of a prescribed wavelength band, but transmits light energy of other different wavelength bands, and that different types of semi-transmissive patterns block the light energy of different wavelength bands.

According to the configuration in the above description, on the exposure mask 1a of Embodiment 1 of the present invention, the first semi-transmissive pattern 12a is formed on the surface on one side with respect to the direction of the thickness, and the second semi-transmissive pattern 13a is formed on the surface on the other side. However, the surface on which any of the semi-transmissive patterns are formed is not limited as such. An alternative possible configuration is that multiple types of semi-transmissive patterns are layered on one surface, for example.

Here, specific examples of the relationship between the pigment contained in the semi-transmissive patterns and the wavelength band of the light energy (i.e., the color of the light) are discussed.

Copper (atomic symbol: Cu) and cobalt (atomic symbol: Co) have a property of absorbing the light energy of an approximately 435 to 485 nm wavelength band (blue light). Chrome (atomic symbol: Cr) and iron (atomic symbol: Fe) have a property of absorbing the light energy of an approximately 500 to 550 nm wavelength band (green light). Silver (atomic symbol: Ag) and nickel (atomic symbol: Ni) have a property of absorbing the light energy of an approximately 580 to 590 nm wavelength band (yellow light). Gold (atomic symbol: Au) has a property of absorbing the light energy of an approximately 650 to 780 nm wavelength band (red light).

As a result, semi-transmissive patterns containing copper or cobalt as a pigment can block the light energy of an approximately 435 to 485 nm wavelength band and transmit the light energy of other wavelength bands. Semi-transmissive patterns containing chrome or iron as a pigment can block the light energy of an approximately 500 to 550 nm wavelength band and transmit the light energy of other wavelength bands. Semi-transmissive patterns containing silver or nickel as a pigment can block the light energy of an approximately 580 to 590 nm wavelength band and transmit the light energy of other wavelength bands. Semi-transmissive patterns containing gold as a pigment can block the light energy of an approximately 650 to 780 nm wavelength band and transmit the light energy of other wavelength bands.

As an exposure device, one including a high-pressure mercury vapor lamp light source that can deliver the light energy of 436 nm, 546 nm, and/or 579 nm wavelength band(s) can be used. The light energy of a 436 nm wavelength is blocked by the semi-transmissive pattern containing copper or cobalt as a pigment. The light energy of a 546 nm wavelength is blocked by a semi-transmissive pattern containing chrome or iron as a pigment. The light energy of a 579 nm wavelength is blocked by a semi-transmissive pattern containing silver or nickel as a pigment.

As a result, a combination of, for example, an exposure mask on which a semi-transmissive pattern containing copper or cobalt as a pigment and a semi-transmissive pattern containing chrome or iron as an pigment are formed, and an exposure device that can deliver the light energy of a 436 nm wavelength and the light energy of a 546 nm wavelength, can be used.

That is, the light energy of a 436 nm wavelength delivered by an exposure device (the light source of the exposure device) is blocked by a semi-transmissive pattern containing copper or cobalt as a pigment, but passes through a semi-transmissive pattern containing chrome or iron as a pigment. Consequently, the semi-transmissive pattern containing copper or cobalt as a pigment is projected over the exposure object (i.e., a photoresist material). The projected portion is not irradiated with the light energy, and other portion is irradiated with the light energy. On the other hand, the light energy of a 546 nm wavelength delivered by the exposure device (the light source of the exposure device) is blocked by a semi-transmissive pattern containing chrome or iron as a pigment, but passes through the semi-transmissive pattern containing copper or cobalt as a pigment. Consequently, the semi-transmissive pattern containing chrome or iron as a pigment is projected over the exposure object (i.e., a photoresist material). The projected portion is not irradiated with the light energy, and other portion is irradiated with the light energy.

Thus, by using the exposure mask and the exposure device together, multiple types of elements, which are conventionally formed using a plurality of exposure masks, can be formed using a single common exposure mask.

Next, a method of manufacturing a substrate for display panels and a method of manufacturing the display panel according to embodiments of the present invention for which the photolithography method is employed are described. A display panel 7 according to an embodiment of the present invention is an active matrix type liquid crystal display panel. Also, a substrate 3 of Embodiment 2 of the present invention is a TFT array substrate used in active matrix type liquid crystal display panels, and a substrate 6 of Embodiment 3 of the present invention is an opposite substrate (i.e., color filter).

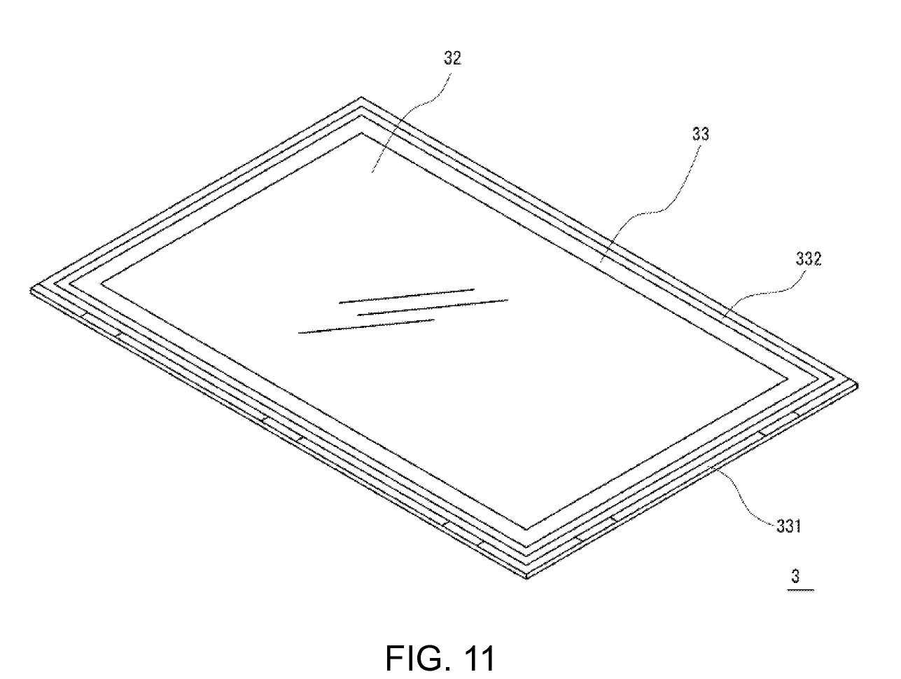

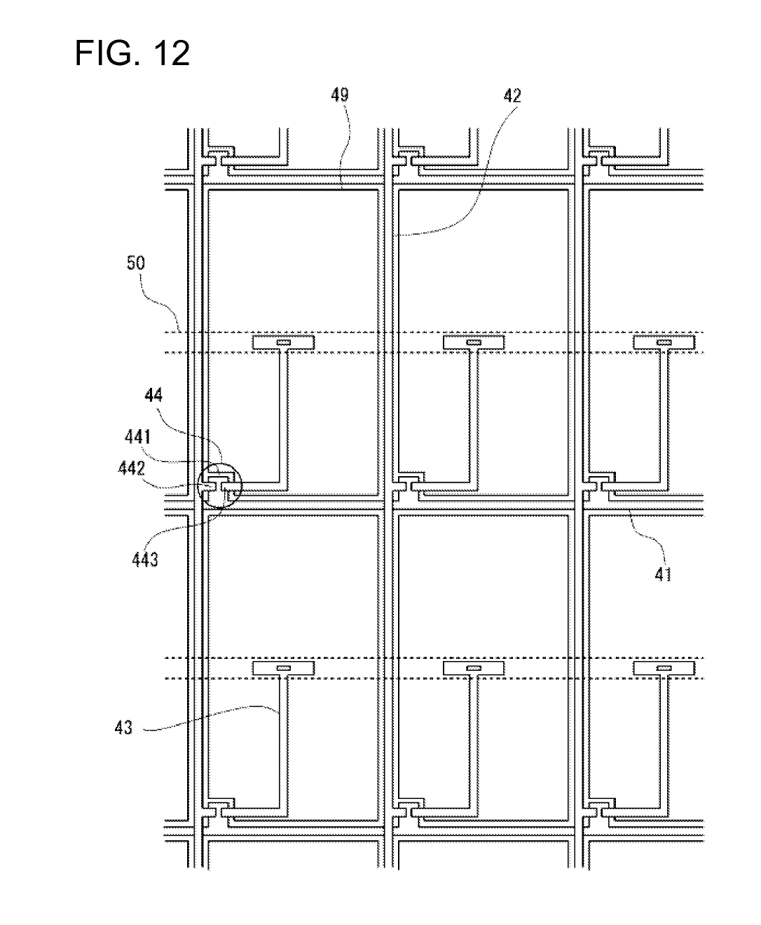

FIG. 11 is an exterior perspective view schematically showing the configuration of a substrate 3 of Embodiment 2 of the present invention (TFT array substrate for active matrix type liquid crystal display panels). FIG. 12 is a plan view schematically showing the configuration of pixels formed on the substrate 3 of Embodiment 2 of the present invention. Certain wirings and elements other than those shown in FIG. 11 are also formed on the substrate 3 of Embodiment 2 of the present invention, but they are omitted in the figure.

As shown in FIG. 11, an active region 32 (also referred to as “display region”) and a panel frame region 33 bordering the active region 32 are provided on the substrate 3 of Embodiment 2 of the present invention.

The active region 32 is a region where the prescribed number of (a plurality of) pixels are formed. Specifically, the outer contour of the active region 32 is formed approximately into a quadrangle, and as shown in FIG. 12, a prescribed number of pixel electrodes 49 are formed in a matrix in the active region 32. Also, in the active region 32, as shown in FIG. 12, a prescribed number of gate wirings 41 are arranged approximately in parallel with each other and a prescribed number of the reference wirings 50 are disposed between the gate wirings 41 in parallel with the gate wirings 41. Between a prescribed reference wiring 50 and a prescribed pixel electrode 49, a storage capacitance, which is an electrostatic capacitance, is formed. Further, a prescribed number of source wirings 42 are formed to extend in the direction approximately perpendicular to the direction in which the gate wirings 41 and the reference wirings 50 extend.

The gate wirings 41 and the reference wirings 50 are formed in the same layer, and the source wirings 42 are formed in a layer that is different from the layer in which the gate wirings 41 and the reference wirings 50 are formed. Also, a layer of the insulating film 45 (i.e., gate insulating film) (not shown) is formed between the layer in which the gate wirings 41 and the reference wirings 50 are formed and the layer in which the source wirings 42 are formed. That is, the source wirings 42 cross the gate wirings 41 and the reference wirings 50 at a different height, sandwiching the insulating film 45. For this reason, at the locations where the source wirings 42 intersects with the gate wirings 41 at a different height, and at the locations where the source wirings 42 intersects with the reference wirings 50 at a different height, the source wirings 42 are not electrically connected to the gate wiring 41 or the reference wiring 50 and are isolated.

The gate wiring 41 is also called by names such as “scan line” or “gate bus line.” The source wiring 42 is also called by names such as “data line” or “source bus line.” The reference wiring 50 is also called by names such as “auxiliary capacitance line,” “holding capacitance line,” “auxiliary capacitance bus line,” or “Cs wiring.” Holding capacitance is also called by names such as “auxiliary capacitance” or “storage capacitance.”

Also, as shown in FIG. 12, thin film transistors (TFT) 44 are provided near the intersections of the gate wirings 41 and the source wirings 42, which function as switching elements that drive the pixel electrodes 49. The gate electrode 441 of each thin film transistor 44 is electrically connected to the prescribed gate wiring 41, the source electrode 442 is electrically connected to the prescribed source wiring 42, and the drain electrode 443 is electrically connected to the prescribed pixel electrode 49 through the drain wiring 43. Specifically, the gate electrode 441 of the thin film transistor 44 is unifiedly formed with a prescribed gate wiring 41, of the same conductive material of which the prescribed gate wiring 41 is formed. The source electrode 442 is unifiedly formed with a prescribed source wiring 42, of the same conductive material of which the prescribed source wiring 42 is formed. The drain electrode 443 is unifiedly formed with a prescribed drain wiring 43, of the same conductive material of which the prescribed drain wiring 43 is formed. Also, the drain electrode 443 is electrically connected to a prescribed pixel electrode 49 through a prescribed drain wiring 43.

The reference wiring 50 has a portion that overlaps a prescribed drain wiring 43 through the insulating film 45. The portion that overlaps the drain wiring 43 becomes a holding capacitance. Because the drain wiring 43 is electrically connected to the pixel electrode 49, a capacitance is formed between the reference wiring 50 and the pixel electrode 49 (through the drain wiring 43).

As shown in FIG. 11, the panel frame region 33 is a region externally bordering the active region 32. It is an approximately quadrilateral frame-shaped region provided along the periphery of the substrate 3 of Embodiment 2 of the present invention. The panel frame region 33 includes terminal regions 331 and seal pattern regions 332.

The terminal regions 331 are thin band-shaped regions provided on prescribed sides of the four sides of the panel frame region 33 (in the case of the substrate 3 of Embodiment 2 of the present invention, the prescribed sides are two sides, one is a longer side and the other is a shorter side) along the periphery of the panel frame region 33. The terminal region 331 provided along a prescribed side of the panel frame region 33 (the shorter side in the case of the substrate 3 of Embodiment 2 of the present invention) is the area to which circuit substrates (TAB (Tape Carrier Package), for example), which take a form of film or sheet and have thereon driver ICs or driver LSIs (hereinafter referred to as “gate driver”) that generate gate signals (also referred to as “gate pulses,” “selection pulses,” or the like) for driving prescribed thin film transistors 44, are attached. The terminal region 331 provided along the other prescribed side of the panel frame region 33 (the longer side in the case of the substrate 3 of Embodiment 2 of the present invention) is the area to which circuit substrates, which take a form of film or sheet and have thereon driver ICs or driver LSIs (hereinafter referred to as “source driver”) that generate image signals (also referred to as “data signals,” “gradation signals,” or the like) to be sent to prescribed pixel electrodes 49, are attached.

In the terminal region 331, a prescribed number of wiring electrode terminals (not shown) are disposed with prescribed intervals between them. The wiring electrode terminals have a prescribed number (plurality) of connecting lands made of a conductive material, for example. Connecting lands provided on the terminal region 331 are also referred to as “wiring electrode terminals,” but in the present invention, “a wiring electrode terminal” refers to a collection of a plurality of connecting lands formed as a unit.

Of the four sides of the panel frame region 33, along a prescribed side(s) on which the terminal region 331 is provided (generally, one shorter side or both shorter sides; one shorter side in the case of the substrate 3 of Embodiment 2 of the present invention), wirings (not shown) that electrically connect prescribed connecting lands of prescribed wiring electrode terminals and prescribed gate wirings 41 provided in the active region 32 together are formed. Also, along the other prescribed side(s) on which the terminal region 331 is provided (generally, one longer side or both longer sides; one longer side in the case of the substrate 3 of Embodiment 2 of the present invention), wirings (not shown) that electrically connect prescribed connecting lands of prescribed wiring electrode terminals and prescribed source wirings 42 provided in the active region 32 together are formed.

According to such a configuration, when a circuit substrate with a gate driver mounted thereon is attached to the terminal region 331 provided along the prescribed side(s), gate signals generated by the gate driver are sent to prescribed gate wirings 41 formed in the active region 32 via prescribed connecting lands of the wiring electrode terminals and wirings provided in the panel frame region 33. As a result, gate signals can be sent to the gate electrodes 441 of prescribed thin film transistors 44 connected to respective gate wirings 41.

Also, when a circuit substrate with a source driver mounted thereon is attached to the terminal region 331 provided along the other prescribed side(s), image signals generated by the source driver are sent to prescribed source wirings 42 formed in the active region 32 through prescribed connecting lands of the wiring electrode terminals and prescribed wirings formed in the panel frame region 33. As a result, image signals are sent to the source electrodes 442 of prescribed thin film transistors 44 connected to respective source wirings 42.

Further, along a prescribed side of the panel frame region 33 (specifically, the side along which wirings that connect the gate wiring 41 provided in the active region 32 and prescribed connecting lands of prescribed wiring electrode terminals are formed), prescribed wirings (not shown) that are electrically connected to the reference wiring 50 provided in the active region 32 are formed. As a result, through the circuit substrate on which a source driver is mounted or the circuit substrate on which a gate driver is mounted and the prescribed wirings, prescribed signals can be sent to prescribed reference wirings 50 provided in the active region 32.

Next, a method of manufacturing the substrate 3 of Embodiment 2 of the present invention is described. In the method of manufacturing the substrate 3 of Embodiment 2 of the present invention, a photolithography method according to an embodiment of the present invention is used in steps of forming prescribed elements such as prescribed wirings and prescribed insulating films.

Specifically, a photolithography method according to an embodiment of the present invention is used in the step of forming the gate wiring 41, reference wiring 50, and gate electrode 441 of the thin film transistor 44, and in the step of forming the semiconductor film 46. Also, in the step of conducting an exposure process, a single common exposure mask (the exposure mask 1b of Embodiment 2 of the present invention) is used. Similarly, the photolithography method according to an embodiment of the present invention is used in the step of forming the source wiring 42, the drain wiring 43, the source electrode 442 and drain electrode 443 of the thin film transistor 44, and in the step of forming the organic insulating film 48. In the step of the exposure process, a common exposure mask (the exposure mask 1c of Embodiment 3 of the present invention) is used.

The exposure device used in the photolithography method according to an embodiment of the present invention is configured to be able to selectively deliver the light energy of the first wavelength band and the light energy of the second wavelength band, which is different from the first wavelength band. An alternative possible configuration is that two exposure devices are used, where one of them can deliver the light energy of the first wavelength band and the other can deliver the light energy of the second wavelength band. For example, the light energy of the first wavelength band may be the light energy of a short wavelength band (i.e., light energy of a blue wavelength band), and the light energy of the second wavelength band may be the light energy of a long wavelength band (i.e., light energy of a red wavelength band).

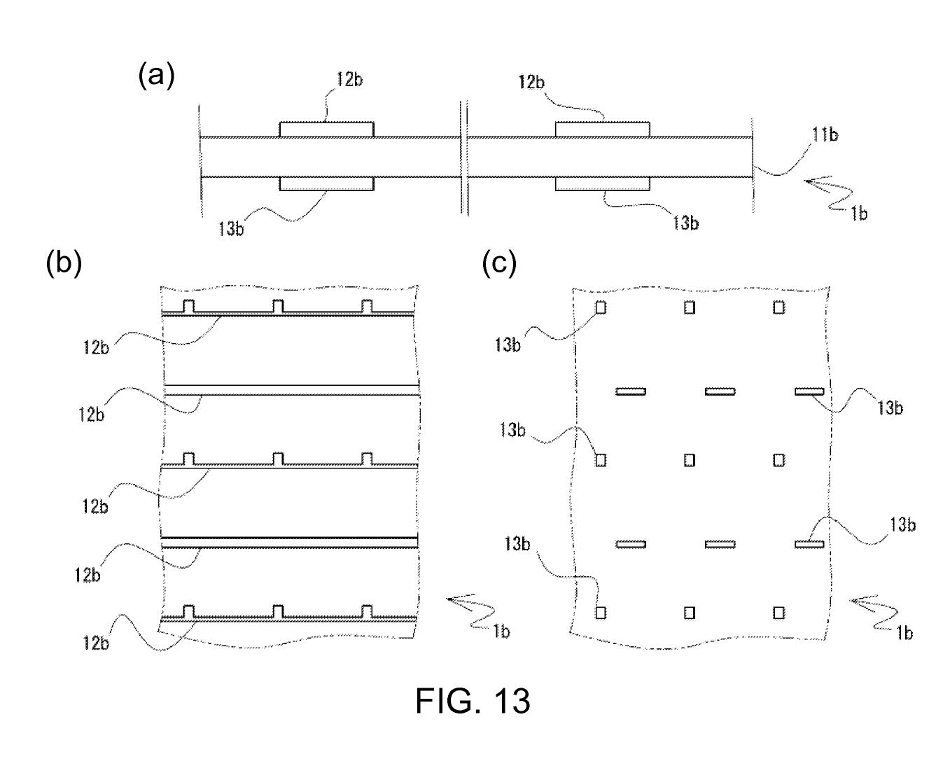

FIG. 13 schematically shows the configuration of the exposure mask 1b of Embodiment 2 of the present invention. FIG. 13(a) is a cross-sectional view illustrating the cross-sectional configuration, FIG. 13(b) is a plan view illustrating the first semi-transmissive pattern 12b, and FIG. 13(c) is a plan view illustrating the second semi-transmissive pattern 13b. FIG. 13(a), FIG. 13(b), and FIG. 13(c) show a portion of the exposure mask 1b of Embodiment 2 of the present invention. FIG. 13(a) is a schematic view for explanation, and not a cross-sectional view taken along a particular line.

As shown in FIG. 13(a), the exposure mask 1b of Embodiment 2 of the present invention has a transparent substrate 11b (a substrate that can transmit both the light energy of the first wavelength band and the light energy of the second wavelength band) made of glass or the like. As shown in FIG. 13(a) and FIG. 13(b), a first semi-transmissive pattern 12b is formed on the surface of the transparent substrate 11b on one side with respect to the direction of the thickness. Also, as shown in FIG. 13(a) and FIG. 13(c), a second semi-transmissive pattern 13b is formed on the surface of the transparent substrate 11b on the other side with respect to the direction of the thickness. An alternative possible configuration is that both the first semi-transmissive pattern 12b and the second semi-transmissive pattern 13b are formed on one surface of the transparent substrate 11b.

The first semi-transmissive pattern 12b can block the light energy of the first wavelength band, and can transmit the light energy of the second wavelength band. For example, if the light energy of the first wavelength band is light energy of blue wavelength band and if the light energy of the second wavelength band is light energy of red wavelength band, a configuration in which the first semi-transmissive pattern 12b is formed of a material having a blue pigment is employed. According to such a configuration, when the light energy of the first wavelength band is delivered, the blue pigment absorbs or reflects the light energy of the first wavelength band, and therefore the light energy is blocked. The blue pigment, on the other hand, does not absorb or reflect the light energy of the second wavelength band, and therefore the light energy is transmitted.

The first semi-transmissive pattern 12b is a pattern for forming the gate wiring 41, the reference wiring 50, and the gate electrode 441 of the thin film transistor 44. As shown in FIG. 13(b), the first semi-transmissive pattern 12b is formed into the dimensions and shape corresponding to those of the gate wiring 41, the reference wiring 50, and the gate electrode 441 of the thin film transistor 44 (i.e., into approximately the same dimensions and shape).

Also, as shown in FIG. 13(a) and FIG. 13(c), a second semi-transmissive pattern 13b is formed on the surface of the transparent substrate 11b on the other side with respect to the direction of the thickness. The second semi-transmissive pattern 13b can block the light energy of the second wavelength band, and transmit the light energy of the first wavelength band. For example, if the light energy of the first wavelength band is the light energy of a blue wavelength band and if the light energy of the second wavelength band is the light energy of a red wavelength band, a configuration in which the second semi-transmissive pattern 13b is formed of a material having a red pigment is employed. According to such a configuration, when the light energy of the second wavelength band is delivered, the red pigment absorbs or reflects the light energy of the second wavelength band, and therefore the light energy is blocked. The red pigment, on the other hand, does not absorb or reflect the light energy of the first wavelength band, and therefore the light energy is transmitted.

The second semi-transmissive pattern 13b is a pattern for forming the semiconductor film 46 of a prescribed shape at a prescribed location. As shown in FIG. 13(c), the second semi-transmissive pattern 13b is formed into the dimensions and shape corresponding to those of the semiconductor film 46 (i.e., into approximately the same dimensions and shape).

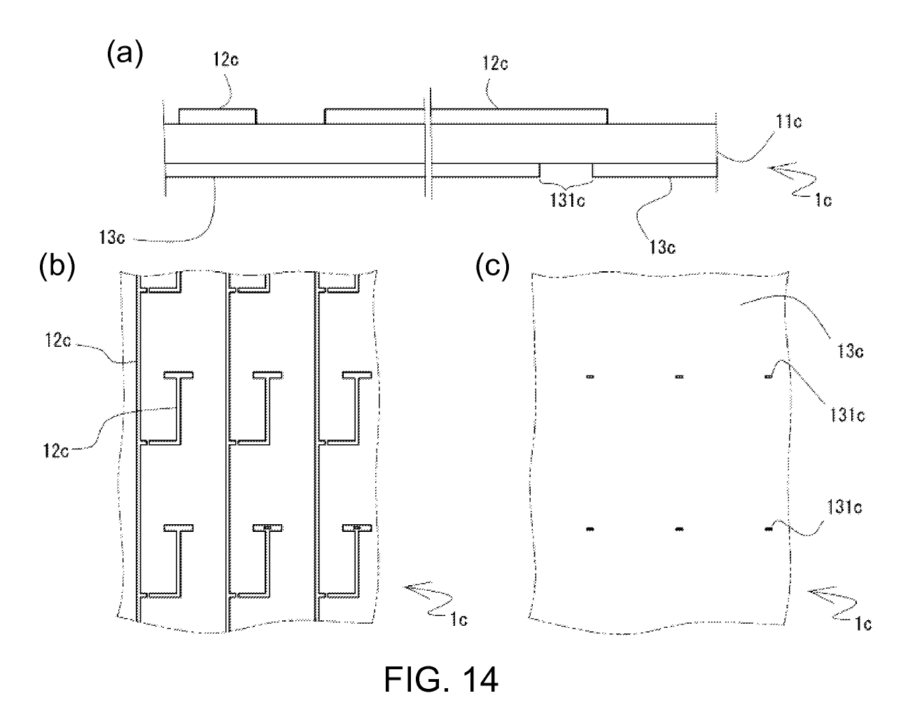

FIG. 14 schematically shows the configuration of the exposure mask 1c of Embodiment 3 of the present invention. FIG. 14(a) is a cross-sectional view illustrating the cross-sectional structure, FIG. 14(b) is a plan view illustrating the first semi-transmissive pattern 12c, and FIG. 14(c) is a plan view illustrating the second semi-transmissive pattern 13c. FIG. 14(a), FIG. 14(b), and FIG. 14(c) all show a portion of the exposure mask 1c of Embodiment 3 of the present invention. FIG. 14(a) is a schematic view for explanation, and not a cross-sectional view taken along a particular line.

As shown in FIG. 14(a), the exposure mask 1c of Embodiment 3 of the present invention has a transparent substrate 11c (a substrate that can transmit both the light energy of the first wavelength band and the light energy of the second wavelength band) made of glass or the like. As shown in FIG. 14(a) and FIG. 14(b), a first semi-transmissive pattern 12c is formed on the surface of the transparent substrate 11c on one side with respect to the direction of the thickness. Also, a second semi-transmissive pattern 13c is formed on the surface of the transparent substrate 11c on the other side with respect to the direction of the thickness. An alternative possible configuration is that both the first semi-transmissive pattern 12c and the second semi-transmissive pattern 13c are formed on one surface of the transparent substrate 11c.

In a manner similar to exposure mask 1b of Embodiment 2 of the present invention, the first semi-transmissive pattern 12c of the exposure mask 1c of Embodiment 3 of the present invention can block the light energy of the first wavelength band and can transmit the light energy of the second wavelength band. Also, the second semi-transmissive pattern 13c can block the light energy of the second wavelength band and can transmit the light energy of the first wavelength band.

The first semi-transmissive pattern 12c of the exposure mask 1c of Embodiment 3 of the present invention is a pattern for forming the source wiring 42, the drain wiring 43, and the source electrode 442 and drain electrode 443 of the thin film transistor 44. As shown in FIG. 14(b), the first semi-transmissive pattern 12c is formed into the dimensions and shape corresponding to those of the source wiring 42, drain wiring 43, and the source electrode 442 and drain electrode 443 of the thin film transistor 44 (into approximately the same dimensions and shape).

The second semi-transmissive pattern 13c of the exposure mask 1c of Embodiment 3 of the present invention is a pattern for forming contact holes for electrically connecting the pixel electrode 49 and the drain wiring 43 at prescribed locations on the organic insulating film 48. As shown in FIG. 14(c), the second semi-transmissive pattern 13c is formed over the approximately entire surface of the transparent substrate 11c on the other side with respect to the direction of the thickness, and openings 131c are formed into the dimensions and shapes corresponding to those of the contact holes (i.e., into approximately the same dimensions and shapes) at locations corresponding to the locations where the contact holes will be formed.

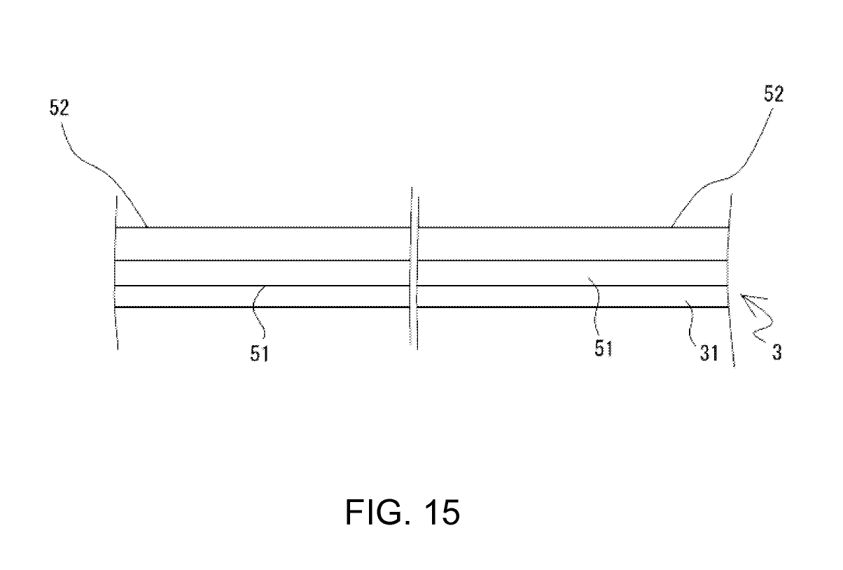

FIG. 15 to FIG. 29 are cross-sectional views schematically showing a method of manufacturing the substrate 3 of Embodiment 2 of the present invention. These figures schematically illustrate the cross-sectional structure of the substrate 3 of Embodiment 2 of the present invention, and are not cross-sectional views taken along a particular line.

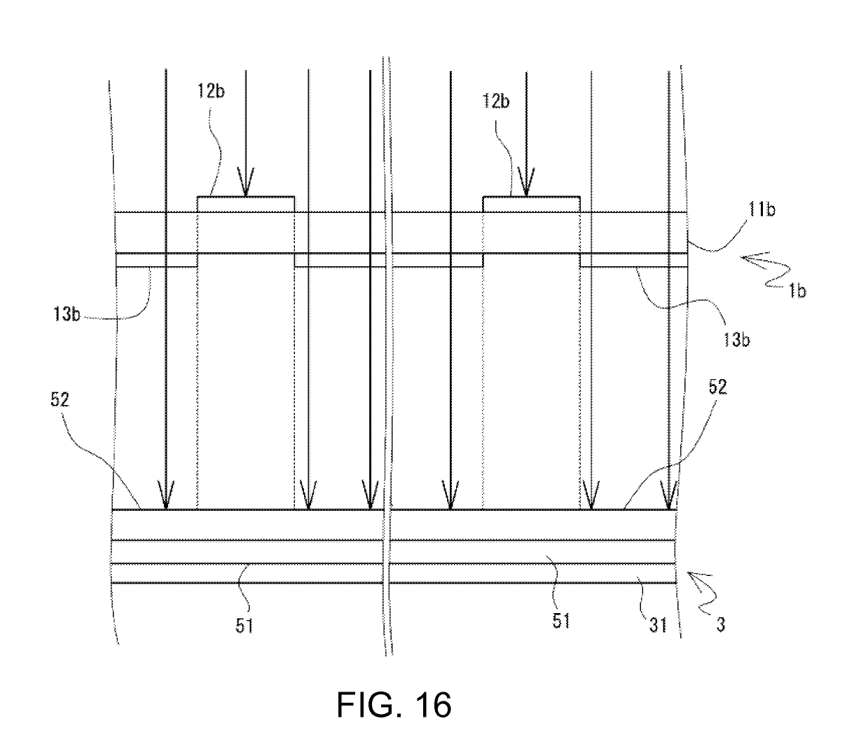

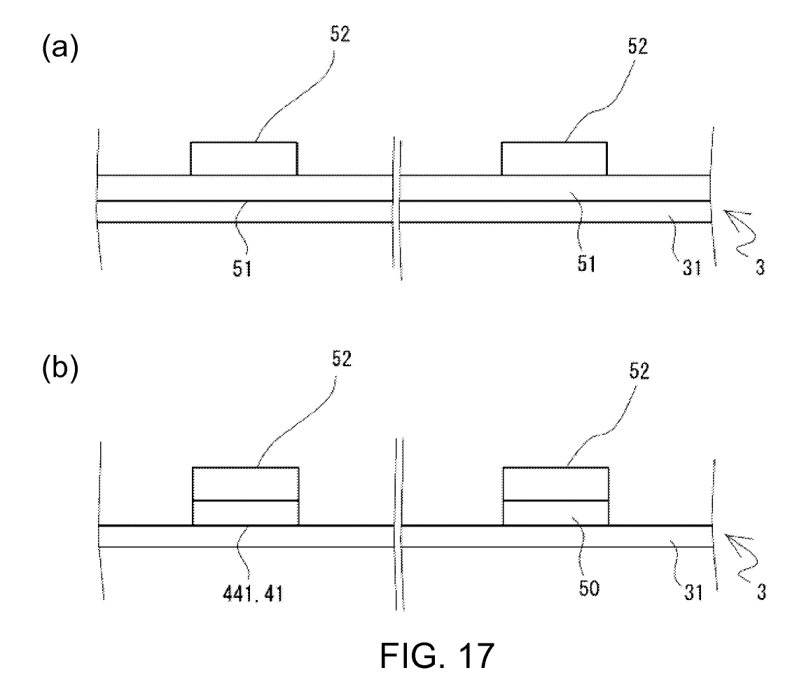

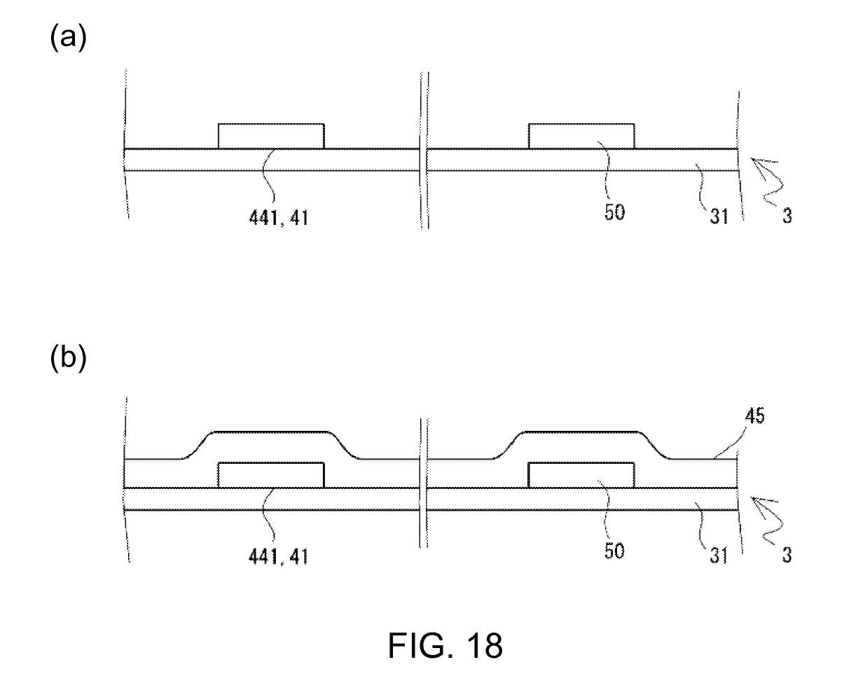

As shown in FIG. 15, FIG. 16, FIG. 17, and FIG. 18(a), gate wirings 41, reference wirings 50, and gate electrodes 441 of the thin film transistors 44 are formed on the surface of the transparent substrate 31 made of glass or the like.

FIG. 15 schematically shows the step of forming a first conductive film 51 and a first photoresist material film 52 on a single surface of the transparent substrate 31.

Specifically, as shown in FIG. 15, the first conductive film 51 is formed over the entire single surface of the transparent substrate 31. The first conductive film 51 has a single layer or a multi-layer structure made of chrome, tungsten, molybdenum, aluminum, or the like. For forming the first conductive film 51, various known sputtering methods or the like can be employed. The thickness of the first conductive film 51 is not especially limited, but a thickness of about 300 nm, for example, is applicable.

Also, as shown in FIG. 15, on the surface of the first conductive film 51, a first photoresist material film 52 is formed, covering the first conductive film 51. For the first photoresist material film 52, a photoresist material whose solubility in developer changes by being irradiated with the light energy of the first wavelength band is used. That is, if the first photoresist material film 52 is made of a positive photoresist material, by being exposed to the light energy of the first wavelength band in the exposure process, the portion irradiated with the light energy is removed in the development process. There is no special limitation to the method of forming the first photoresist material film 52. For example, a solution that will be the material for the first photoresist material film 52 can be applied on the surface of the first conductive film 51 using a spin coater, and then be cured.

Next, as shown in FIG. 16, an exposure process is conducted using the exposure mask 1b of Embodiment 2 of the present invention and an exposure device. FIG. 16 schematically shows an exposure process of the photolithography method used in the step of forming the gate wiring 41, the reference wiring 50, and the gate electrode 441 of the thin film transistor 44. The arrows in the figure schematically indicate the light energy. In this exposure process, the exposure device delivers the light energy of the first wavelength band. That is, on the surface of the first photoresist material film 52, the exposure mask 1b of Embodiment 2 of the present invention is placed, and through the exposure mask 1b of Embodiment 2 of the present invention, the first photoresist material film 52 is irradiated with the light energy of the first wavelength band.

When the exposure device delivers the light energy of the first wavelength band, a portion of the light energy of the first wavelength band is blocked by a first semi-transmissive pattern 12b of the exposure mask 1b of Embodiment 2 of the present invention, and the remaining light energy passes through the exposure mask 1b of Embodiment 2 of the present invention. Because the light energy of the first wavelength band can pass through the second semi-transmissive pattern 13b, the second semi-transmissive pattern 13b does not become a barrier to the passage of the light energy of the first wavelength band through the exposure mask 1b of Embodiment 2 of the present invention. As a result, the portion of the first photoresist material film 52 over which the first semi-transmissive pattern 12b is projected is not irradiated with the light energy of the first wavelength band, and the remaining portion is irradiated with the light energy of the first wavelength band regardless of the presence of the second semi-transmissive pattern 13b.

Next, as shown in FIG. 17(a), a development process is conducted on the first photoresist material film 52, which went through the exposure process. FIG. 17(a) schematically shows the development process of the photolithography method employed in the step of forming the gate wiring 41, the reference wiring 50, and the gate electrode 441 of the thin film transistor 44. In the development process, if the first photoresist material film 52 is made of a positive photoresist material, the portion of the first photoresist material film 52 irradiated with the light energy of the first wavelength band is removed, and the portion that was not irradiated (i.e., the portion over which the first semi-transmissive pattern 12b was projected) is preserved on the surface of the first conductive film 51. As a result, the first photoresist material film 52 formed into the dimensions and shapes of the gate wiring 41, the reference wiring 50, and the gate electrode 441 of the thin film transistor 44 is preserved on the surface of the first conductive film 51.

Next, as shown in FIG. 17(b), the first conductive film 51 is patterned. FIG. 17(b) schematically shows the step of patterning the first conductive film 51. Through this patterning, the first conductive film 51 is formed into the shape of the gate wiring 41, the reference wiring 50, and the gate electrode 441 of the thin film transistor 44. For the patterning of the first conductive film 51, various known wet etching can be performed. In the configuration where the first conductive film 51 is made of chrome, wet etching using (NH₄)₂[Ce(NH₃)₆]+HNO₃+H₂O solution can be performed.

Then, as shown in FIG. 18(a), the first photoresist material film 52 is removed. FIG. 18(a) is a cross-sectional view schematically showing the step of removing the first photoresist material film 52.

Next, as shown in FIG. 18(b), an insulating film 45 (i.e., gate insulating film) is formed on the surface of the transparent substrate 31, which went through the above-mentioned step. FIG. 18(b) schematically shows the step of forming the insulating film 45. For the insulating film 45, SiNx (silicon nitride) having a thickness of approx. 30 nm or the like can be used. For the formation of the insulating film 45, plasma CVD method or the like can be used. Once the insulating film 45 is formed, in the active region 32, the gate wiring 41, the reference wiring 50, and the gate electrode 441 of the thin film transistor 44 are covered with the insulating film 45.

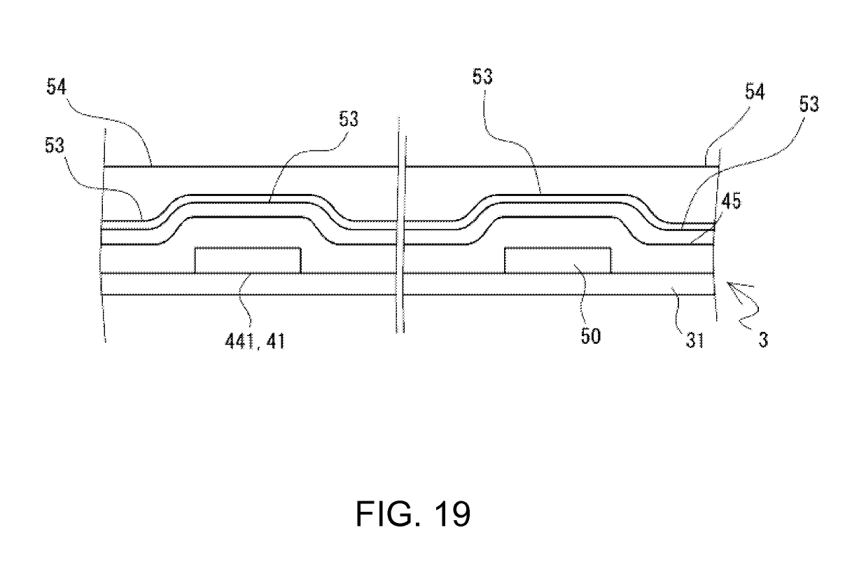

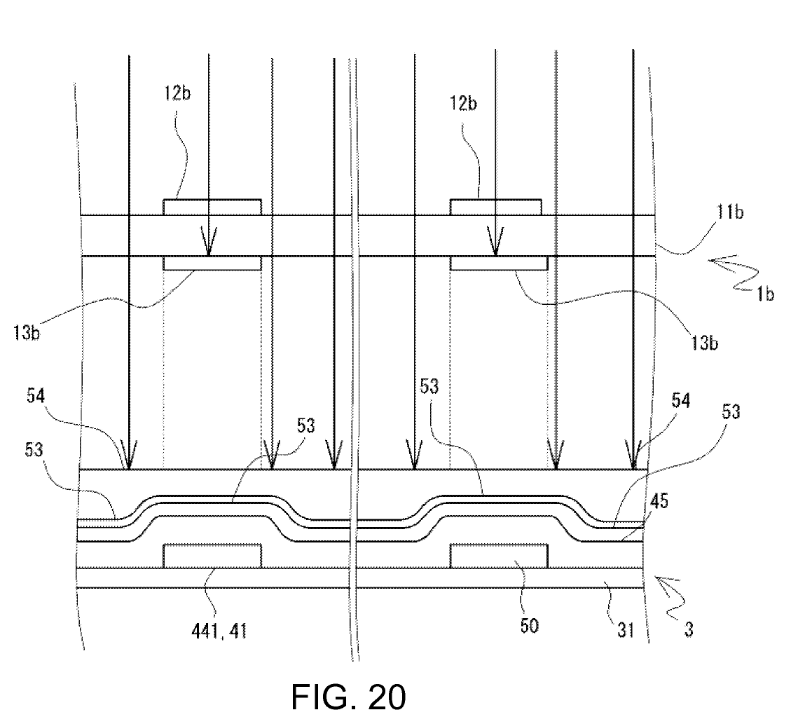

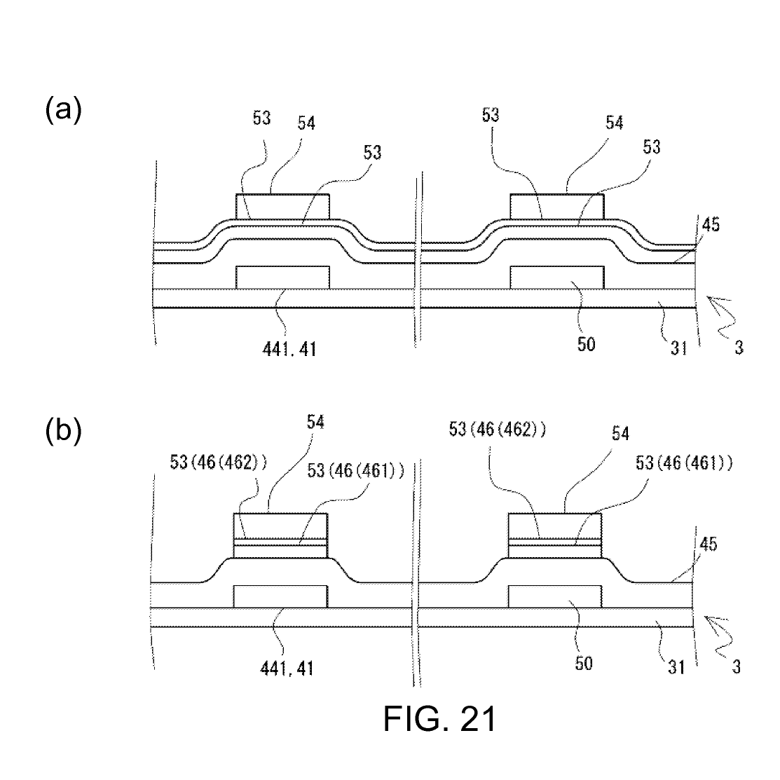

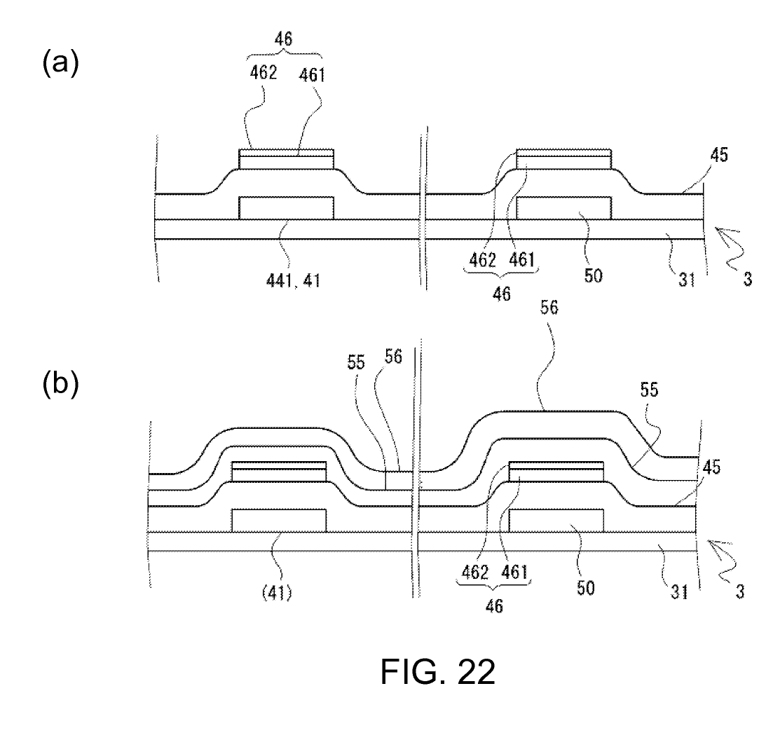

Next, as shown in FIG. 19, FIG. 20, FIG. 21, and FIG. 22(a), in the active region 32, a semiconductor film 46 of a prescribed shape is formed at prescribed locations on the surface of the insulating film 45. Specifically, the semiconductor film 46 is formed at a location where it overlaps the gate electrode 441 through the insulating film 45 and at a location where it overlaps the reference wiring 50 through the insulating film 45. The semiconductor film 46 has a double-layer structure composed of a first sub semiconductor film 461 and a second sub semiconductor film 462. For the first sub semiconductor film 461, amorphous silicon having a thickness of approximately 100 nm or the like can be employed. For the second sub semiconductor film 462, n+ type amorphous silicon having a thickness of approximately 20 nm can be employed.

The first sub semiconductor film 461 functions as an etching stopper layer in the step of forming the source wiring 42, the drain wiring 43, and the like. The second sub semiconductor film 462 is for improving the ohmic contact between the first sub semiconductor film 461 and a source electrode 442 or a drain electrode 443 (will be formed in a later step).

For formation of the semiconductor film 46 (the first sub semiconductor film 461 and the second sub semiconductor film 462), the plasma CVD method and a photolithography method according to an embodiment of the present invention may be employed.

FIG. 19 schematically shows the step of forming a film 53 that is a material for the semiconductor film 46 and a second photoresist material film 54 on one surface of the transparent substrate 31. That is, as shown in FIG. 19, first, the material of the semiconductor film 46 (the first sub semiconductor film 461 and the second sub semiconductor film 462) is deposited on one surface of the transparent substrate 31 that went through the step described above to form a film (the film 53, which is the material of the semiconductor film 46) using the plasma CVD method.

Then, on the surface of the film 53, which is the material of the semiconductor film 46, a second photoresist material film 54 is formed to cover the film 53, which is the material for the semiconductor film 46. The second photoresist material film 54 is formed of a photoresist material whose solubility in developer changes by being irradiated with light energy of the second wavelength band. That is, if the second photoresist material film 54 is made of a positive photoresist material, by being irradiated with the light energy of the second wavelength band, the irradiated portion is removed in the development process, which is conducted later. For the formation of the second photoresist material film 54, a method using a spin coater or the like may be employed.

Then, as shown in FIG. 20, an exposure process is conducted on the second photoresist material film 54 using the exposure mask 1b of Embodiment 2 of the present invention. FIG. 20 schematically shows the exposure process in the photolithography method used in the step of forming the semiconductor film 46. The arrows in the figure schematically indicate the light energy. In this exposure process, the second photoresist material film 54 is irradiated with the light energy of the second wavelength band.

When the exposure device delivers the light energy of the second wavelength band, a portion of the light energy of the second wavelength band is blocked by the second semi-transmissive pattern 13b of the exposure mask 1b of the present invention, and the remaining portion passes through the exposure mask 1b of Embodiment 2 of the present invention. Because the light energy of the second wavelength band can pass through the first semi-transmissive pattern 12b, the first semi-transmissive pattern 12b does not become a barrier to the passage of the light energy of the second wavelength band through the exposure mask 1b of Embodiment 2 of the present invention. As a result, the portion of the second photoresist material film 54 over which the second semi-transmissive pattern 13b is projected is not irradiated with the light energy of the second wavelength band, and the remaining portion is irradiated with the light energy of the second wavelength band regardless of the presence of the first semi-transmissive pattern 12b.

As described above, the second semi-transmissive pattern 13b is a pattern that is formed at the location where the semiconductor film 46 is formed, and has approximately the same dimensions and shape as those of the semiconductor film 46. Consequently, of the second photoresist material film 54, the portion that will form the semiconductor film 46 (where the film 53, which will be the material of the semiconductor film 46, will be preserved) is not irradiated with the light energy of the second wavelength band due to the second semi-transmissive pattern 13b, and the remaining portion is irradiated with the light energy of the second wavelength band.

Next, as shown in FIG. 21(a), a development process is conducted on the second photoresist material film 54, which went through the exposure process. FIG. 21(a) schematically shows the development process of the photolithography method employed in the step of forming the semiconductor film 46. If the second photoresist material film 54 is made of a positive photoresist material, of the second photoresist material film 54, the portion that was irradiated with the light energy of the second wavelength band in the exposure process is removed, and the portion that was not irradiated is preserved. As a result, as shown in FIG. 21(a), at locations where the semiconductor film 46 is to be formed, the second photoresist material film 54 having the same dimensions and shape as the semiconductor film 46 is preserved, and the other portion is removed. Portions of the film 53, which is the material of the semiconductor film 46, located under the removed portion of the second photoresist material film 54 then become exposed.

Next, as shown in FIG. 21(b), the film 53, which is the material of the semiconductor film 46, is patterned and the semiconductor film 46 is formed. FIG. 21(b) schematically shows the step of patterning the film 53, which is the material of the semiconductor film 46. Specifically, the preserved second photoresist material film 54 is used as an etching mask, and through the etching the exposed portion of film 53, which is the material of semiconductor film 46, is removed. This patterning can be done by wet etching using a HF+HNO₃ solution, for example, or dry etching using Cl₂ and SF₆ gas. Thus, the semiconductor film 46 (the first sub semiconductor film 461 and the second sub semiconductor film 462) is formed at a location where it overlap the gate electrode 441 through the insulating film 45 and also at a location where it overlaps the reference wiring 50.

Then, as shown in FIG. 22(a), the preserved second photoresist material film 54 is removed. FIG. 22(a) schematically shows the step of removing the second photoresist material film 54, which is conducted after the development process of the photolithography method employed in the step of forming the semiconductor film 46.

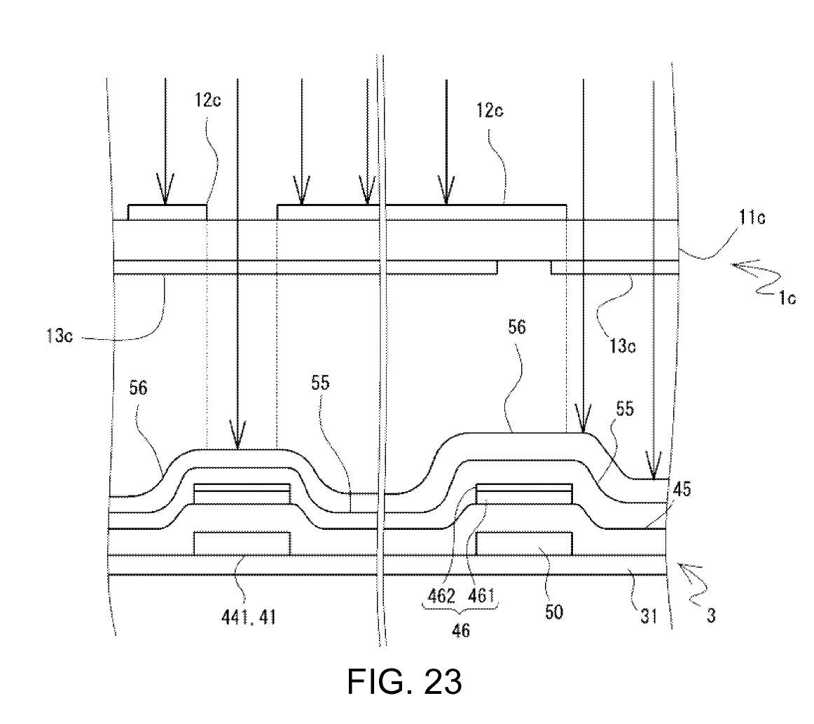

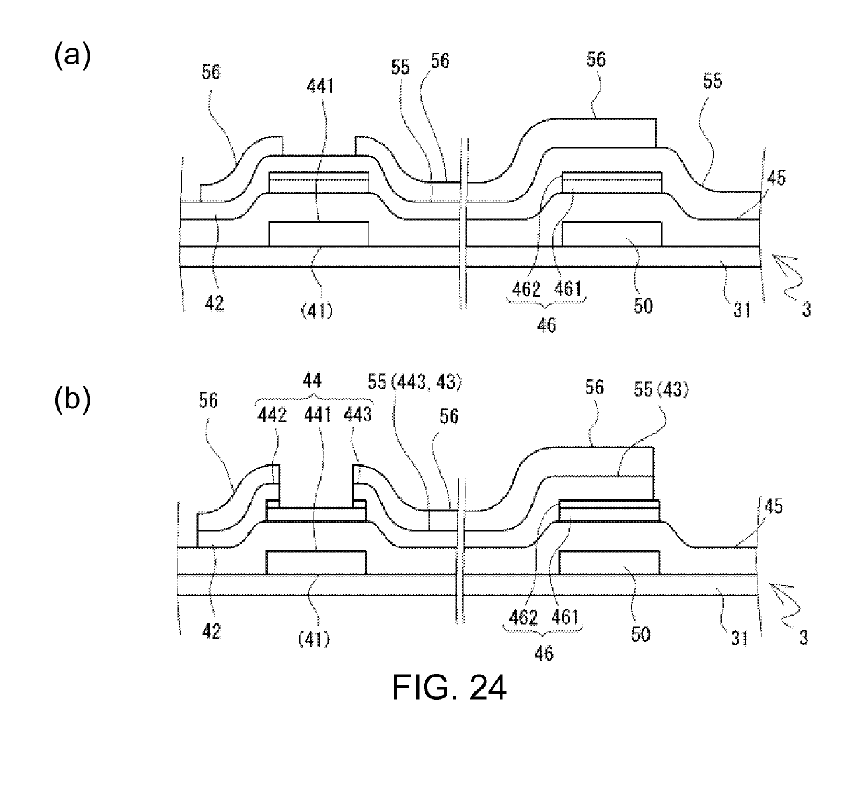

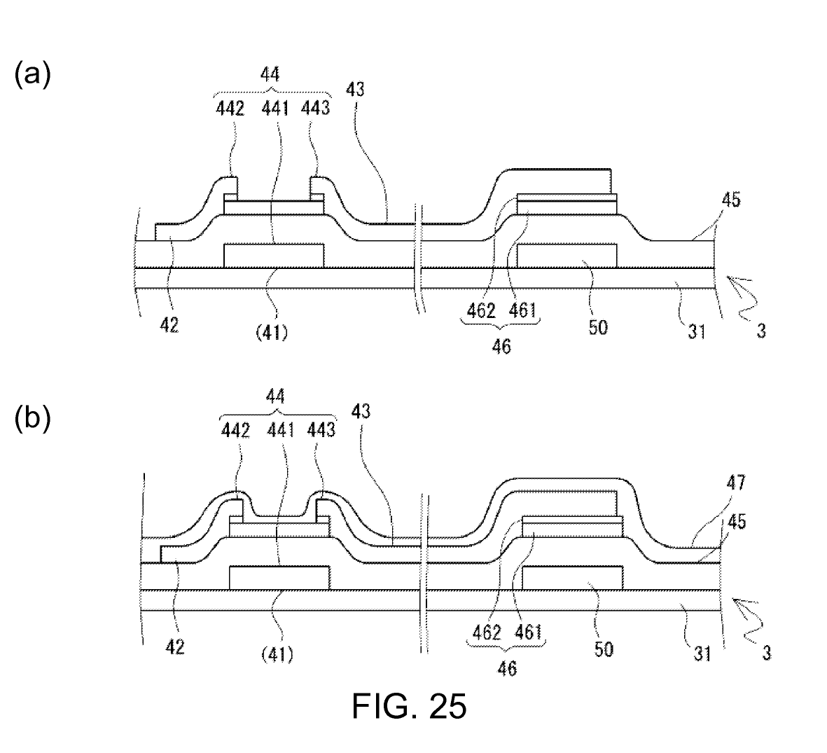

Next, as shown in FIG. 22(b), FIG. 23, FIG. 24, and FIG. 25(a), in the active region 32, the source wiring 42, drain wiring 43, and drain electrode 443 of the thin film transistor 44 are formed of the same material in the same step. For the formation of the source wiring 42, the drain wiring 43, and the drain electrode 443 of the thin film transistor 44, a photolithography method according to an embodiment of the present invention is employed.

FIG. 22(b) is a cross-sectional view schematically showing the step of forming a second conductive film 55 and a third photoresist material film 56 on one surface of the transparent substrate 31. First, as shown in FIG. 22(b), a second conductive film 55 is formed on the surface of the transparent substrate 31, which has gone through the steps described above. The second conductive film 55 has a multi-layered structure of at least two layers composed of titanium, aluminum, chrome, molybdenum, and the like. In the substrate 3 of Embodiment 2 of the present invention, the second conductive film 55 has a double-layer structure. That is, the second conductive film 55 has a double-layer structure composed of a first sub conductive film, which is proximal to the transparent substrate 31, and a second sub conductive film, which is distal to the transparent substrate 31. The first sub conductive film may be formed of titanium or the like. The second sub conductive film may be formed of aluminum or the like. The second conductive film 55 may be formed with various known sputtering method or the like.

Then, on the surface of the second conductive film 55 which is now formed, a third photoresist material film 56 is formed, covering the second conductive film 55. For the third photoresist material film 56, a photoresist material whose solubility in developer changes by being irradiated with the light energy of the first wavelength band is used. That is, if the third photoresist material film 56 is made of a positive photoresist material, by being exposed to the light energy of the first wavelength band in the exposure process, the portion irradiated with the light energy is removed in the development process. There is not special limitation to the method of forming the third photoresist material film 56. For example, a solution for the material for the third photoresist material film 56 can be applied on the surface of the second conductive film 55 using a spin coater and then be cured.

Next, as shown in FIG. 23, an exposure process is conducted using the exposure mask 1c of Embodiment 3 of the present invention and an exposure device. FIG. 23 schematically shows the exposure process of the photolithography method employed for a step of forming the source wiring 42, the drain wiring 43, and the source electrode 442 and drain electrode 443 of the thin film transistor 44. The arrows in the figure schematically indicate the light energy. In this exposure process, the exposure device delivers the light energy of the first wavelength band. That is, on the surface of the third photoresist material film 56, the exposure mask 1c of Embodiment 3 of the present invention is placed, and through the exposure mask 1c of Embodiment 3 of the present invention, the prescribed portion of the third photoresist material film 56 is irradiated with the light energy of the first wavelength band.

When the exposure device delivers the light energy of the first wavelength band, a portion of the light energy of the first wavelength band is blocked by a first semi-transmissive pattern 12c of the exposure mask 1c of Embodiment 3 of the present invention, and the remaining light energy passes through the exposure mask 1c of Embodiment 3 of the present invention. Because the light energy of the first wavelength band can pass through the second semi-transmissive pattern 13c, the second semi-transmissive pattern 13c does not become a barrier to the passage of the light energy of the first wavelength band through the exposure mask 1c of Embodiment 3 of the present invention. As a result, the portion of the third photoresist material film 56 over which the first semi-transmissive pattern 12c is projected is not irradiated with the light energy of the first wavelength band, and the remaining portion is irradiated with the light energy of the first wavelength band regardless of the presence of the second semi-transmissive pattern 13c.

Next, as shown in FIG. 24(a), a development process is conducted on the third photoresist material film 56, which went through the exposure process. FIG. 24(a) schematically shows the development process of the photolithography method employed in the step of forming the source wiring 42, the drain wiring 43, and the source electrode 442 and drain electrode 443 of the thin film transistor 44. If the third photoresist material film 56 is made of a positive photoresist material, of the third photoresist material film 56, the portion that was irradiated with the light energy of the first wavelength band is removed, and the portion that was not irradiated (i.e., the portion over which the first semi-transmissive pattern 12c was projected) is preserved on the surface of the second conductive film 55 through the development process. As a result, on the surface of the second conductive film 55, the third photoresist material film 56 formed into the dimensions and shapes of the source wiring 42, the drain wiring 43, the source electrode 442 and drain electrode 443 of the thin film transistor 44 is preserved.

Next, as shown in FIG. 24(b), the second conductive film 55 is patterned. FIG. 24(b) schematically shows the step of patterning the second conductive film 55. For the patterning of the second conductive film 55, dry etching with Cl₂ and BCl₃ gas and wet etching with phosphoric acid, acetic acid, or nitric acid can be employed. Through this patterning, the source wiring 42, the drain wiring 43, the source electrode 442 and drain electrode 443 of the thin film transistor 44 are formed out of the second conductive film 55. In this patterning, the second sub semiconductor film 462 is also etched using the first sub semiconductor film 461 as the etching stopper layer.

Then, as shown in FIG. 25(a), the remaining third photoresist material film 56 is removed. FIG. 25(a) schematically shows the step of removing the third photoresist material film 56, which is conducted after the development process of the photolithography method employed in the step of forming the source wiring 42, the drain wiring 43, and the source electrode 442 and the drain electrode 443 of the thin film transistor 44.

Once the steps described above are completed, as shown in FIG. 25(a), the thin film transistor 44 (that is, gate electrode 441, source electrode 442, and drain electrode 443), the gate wiring 41, the reference wiring 50, and the source wiring 42 are formed in the active region 32.

Next, as shown in FIG. 25(b), a passivation film 47 is formed on the transparent substrate 31 that has gone through the steps described above. FIG. 25(b) schematically shows the step of forming the passivation film 47. For the passivation film 47, SiNx (silicon nitride) having a thickness of approximately 300 nm can be used. For the formation of the passivation film 47, the plasma CVD method or the like may be employed.

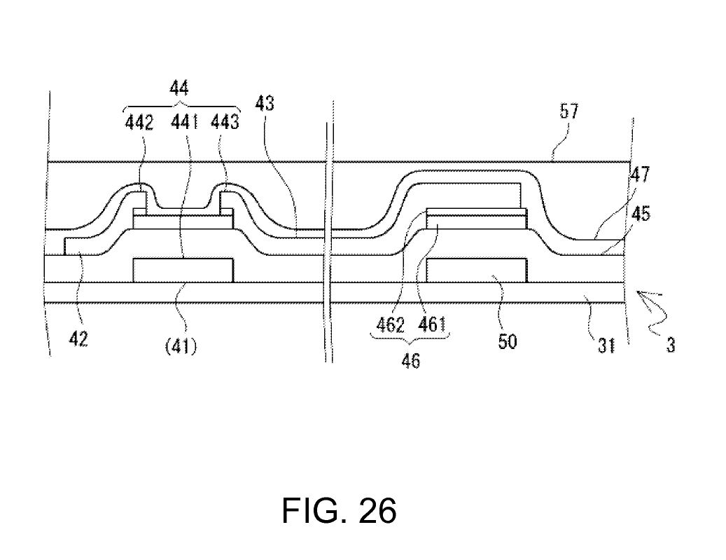

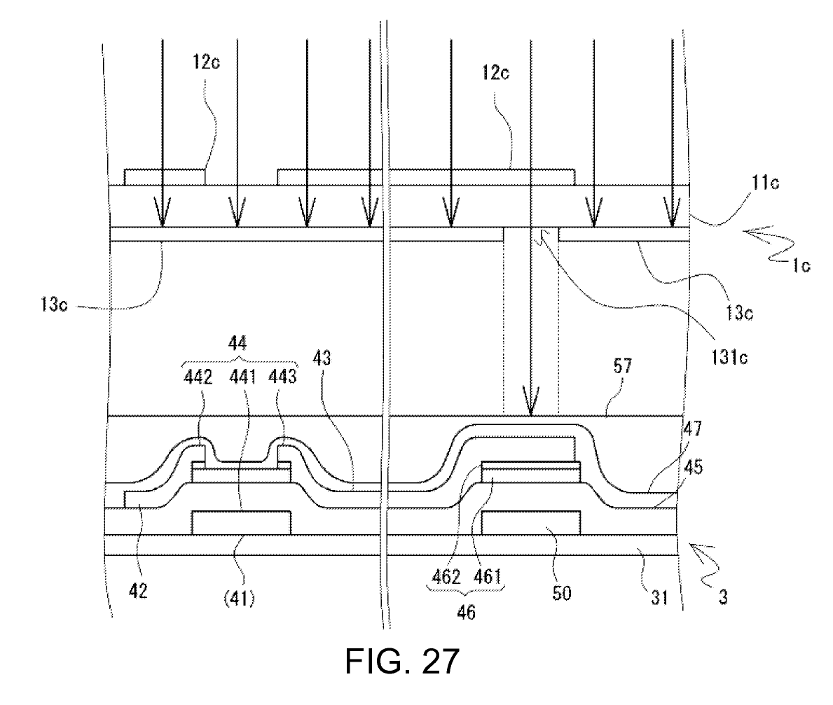

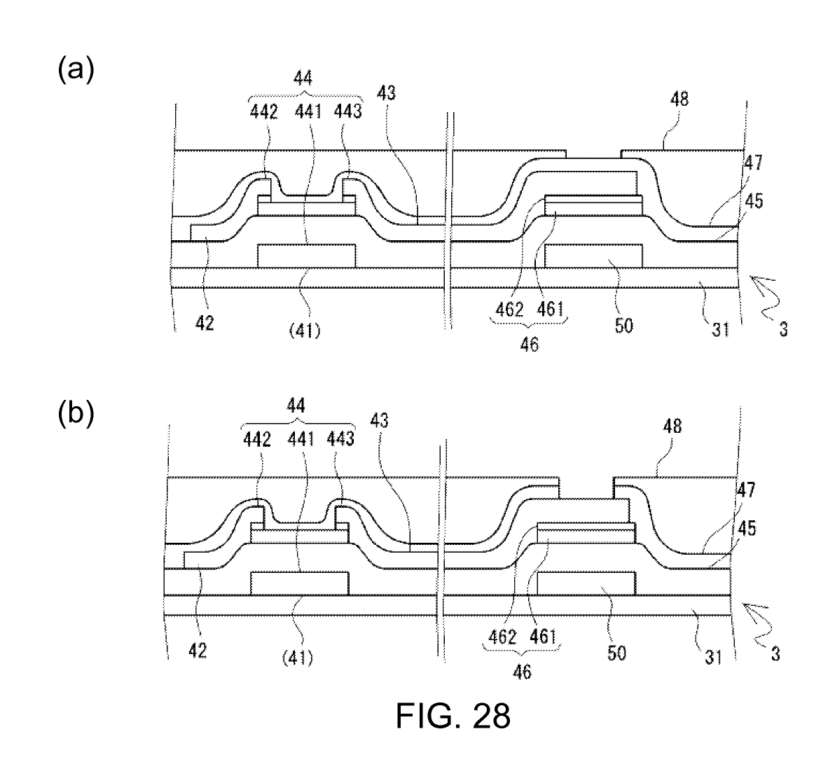

Next, as shown in FIG. 26, FIG. 27, and FIG. 28(a), an organic insulating film 48 is formed on the surface of the passivation film 47. For the organic insulating film 48, a photosensitive acrylic resin material can be used. For the film 57 that is the material of the organic insulating film 48, a resist material whose solubility in developer changes by being irradiated with the light energy of the second wavelength band is used. Also, the film 57 that is the material for the organic insulating film 48 is made of a positive resist material. For the step of forming the organic insulating film 48, the photolithography method according to an embodiment of the present invention is employed.

First, as shown in FIG. 26, the film 57 that is the material of the organic insulating film 48 is formed on the transparent substrate 31 that has gone through the steps described above. FIG. 26 schematically shows the step of forming the film 57 that is the material of the organic insulating film 48. The film 57, which is the material for the organic insulating film 48, may be formed with a method using a spin coater or the like.

Then, as shown in FIG. 27, an exposure process is conducted on the formed film 57 which is the material for the organic insulating film 48. FIG. 27 is a cross-sectional view schematically showing the step of conducting an exposure process on the film 57, which is the material for the organic insulating film 48. Specifically, on the surface of the film 57, which is the material for the organic insulating film 48, the exposure mask 1c of Embodiment 3 of the present invention is placed, and through the exposure mask 1c of Embodiment 3 of the present invention, the film 57, which is the material for the organic insulating film 48, is irradiated with the light energy of the second wavelength band delivered by an exposure device.

When the exposure device delivers the light energy of the second wavelength band, a portion of the light energy of the second wavelength band is blocked by the second semi-transmissive pattern 13c of the exposure mask 1c of Embodiment 3 of the present invention, and the remaining light energy passes through the exposure mask 1c of Embodiment 3 of the present invention. Because the light energy of the second wavelength band can pass through the first semi-transmissive pattern 12c, the first semi-transmissive pattern 12c does not become a barrier to the passage of the light energy of the second wavelength band through the exposure mask 1c of Embodiment 3 of the present invention. As a result, of the film 57 that is the material for the organic insulating film 48, the portion over which the second semi-transmissive pattern 13c is projected is not irradiated with the light energy of the second wavelength band, and the remaining portion is irradiated with the light energy of the second wavelength band regardless of the presence of the first semi-transmissive pattern 12c.

As described above, the second semi-transmissive pattern 13c of the exposure mask 1c of Embodiment 3 of the present invention is a pattern formed over the entirety, and the pattern has openings 131c at locations corresponding to the portions of the organic insulating film 48 where contact holes will be formed. Consequently, of the film 57 that is the material for the organic insulating film 48, the portions where the contact holes will be formed are irradiated with the light energy of the second wavelength band through the openings 131c in the second semi-transmissive pattern 13c, and the remaining portion is not irradiated with the light energy.

Next, as shown in FIG. 28(a), a development process is conducted on the film 57, which is the material for the organic insulating film 48, that went through the exposure process. FIG. 28(a) schematically shows the step of conducting a development process on the film 57, which is the material for the organic insulating film 48. Through the development process, of the film 57, which is the material for the organic insulating film 48, the portions that were irradiated with the light energy of the second wavelength band in the exposure process are removed. The removed portions become contact holes. Through the steps described above, an organic insulating film 48 having prescribed contact holes at prescribed locations is formed.

Next, as shown in FIG. 28(b), the organic insulating film 48, which is now formed, is used as an etching mask to pattern the passivation film 47 and the insulating film 45 by etching. FIG. 28(b) is a cross-sectional view schematically showing the step of patterning the passivation film 47 and the insulating film 45 (it should be noted that the insulating film 45 is not patterned in the area shown in FIG. 28). Through the patterning, of the passivation film 47 and the insulating film 45, the portions exposed through the contact holes formed in the organic insulating film 48 are removed. As a result, contact holes are formed in the passivation film 47. Specifically, as shown in FIG. 28(b), in the active region 32, the portion of the passivation film 47 that covers the end portion of the drain wiring 43 is removed to expose the end portion of the drain wiring 43. For the patterning of the passivation film 47 and the insulating film 45, dry etching with CF₄+O₂ gas or SF₆+O₂ gas may be employed.

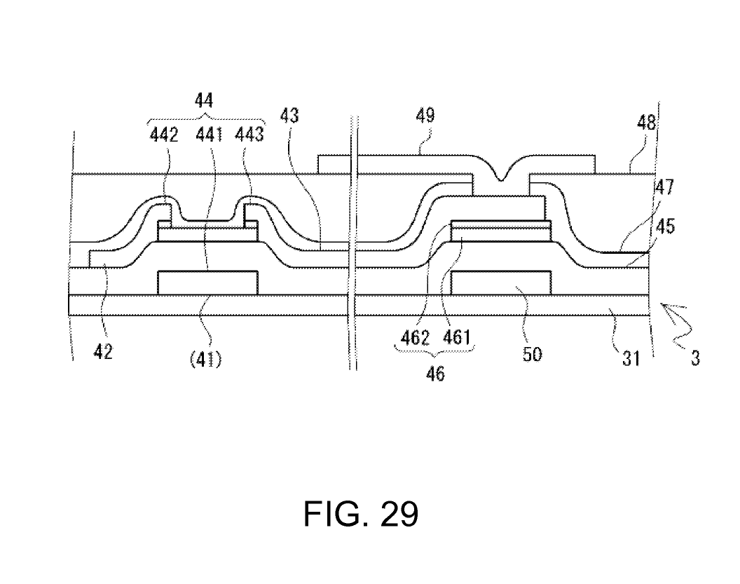

Next, as shown in FIG. 29, a pixel electrode 49 is formed in the active region 32. FIG. 29 schematically shows the step of forming the pixel electrode 49. For the pixel electrode 49, ITO (Indium Tin Oxide) having a thickness of approximately 100 nm, for example, may be used. The pixel electrode 49 may be formed with various known sputtering methods.

Through the steps described above, the substrate 3 of Embodiment 2 of the present invention (a TFT array substrate used for the active matrix type liquid crystal display panel) is manufactured.

Next, a substrate 6 of Embodiment 3 of the present invention (an opposite substrate (i.e., color filter) used in an active matrix type liquid crystal display panel) and a method of manufacturing the substrate 6 are described.

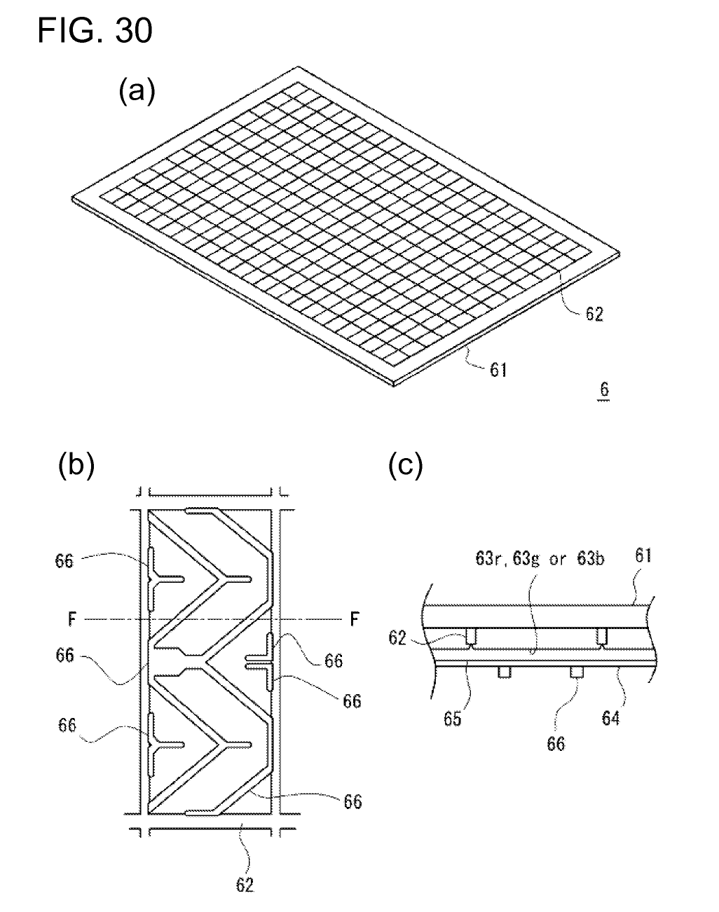

FIG. 30 schematically shows the configuration of the substrate 6 of Embodiment 3 of the present invention. Specifically, FIG. 30(a) is a perspective view schematically showing the overall structure of the substrate 6 of Embodiment 3 of the present invention, FIG. 30(b) is a plan view showing the configuration of one of the pixels formed on the substrate 6 of Embodiment 3 of the present invention, and FIG. 30(c) is a cross-sectional view taken along the line F-F of FIG. 30(b), illustrating the cross-sectional structure of the pixel.

As shown in FIG. 30, regarding the substrate 6 of Embodiment 3 of the present invention, a black matrix 62 is formed on a surface of the transparent substrate 61 made of glass or the like, and inside each of the grids defined by the black matrix 62, a colored layer 63r, 63g, or 63b of colored photosensitive material of red, green, or blue, respectively, is formed. The grids (i.e., pixels), in each of which a colored layer 63r, 63g, or 63b is formed, are arranged in a prescribed order. On the surfaces of the black matrix 62 and the colored layers 63r, 63g, and 63b of respective colors, a protective film 65 is formed, and on the protective film 65, a transparent electrode (common electrode) 64 is formed. On the surface of the transparent electrode (common electrode) 64, alignment control structures 66 that control the alignment of the liquid crystal are formed.

The substrate 6 of Embodiment 3 of the present invention is configured such that pixels having colored layer 63r, 63g, or 63b of respective colors are arranged in stripes. That is, a prescribed number of pixels are arranged in a matrix, and all pixels in one column have the same colored layer 63r, 63g, or 63b. Also, the column of pixels having a red colored layer 63r, the column of pixels having a green colored layer 63g, and the column of pixels having a blue colored layer 63b are arranged periodically in the row direction.

A method of manufacturing the substrate 6 of Embodiment 3 of the present invention includes the step of forming the black matrix, the step of forming the colored layers, the step of forming the protective film, and the step of forming the transparent electrode (common electrode). For the step of forming the black matrix and the step of forming the colored layers, the photolithography method according to embodiments of the present invention is employed. That is, a single common exposure mask (an exposure mask 1d of Embodiment 4 of the present invention) and an exposure device that can selectively deliver the light energy of the first wavelength band and the light energy of the second wavelength band are used. The black matrix 62 is formed from a photoresist material whose solubility in developer changes by being irradiated with the light energy of the first wavelength band, and the colored layers 63r, 63g, and 63b having respective colors are formed from a photoresist material whose solubility in developer changes by being irradiated with the light energy of the second wavelength band. Here, it is assumed that the black matrix 62 and the colored layers 63r, 63g, and 63b having respective colors are formed from positive photoresist materials.

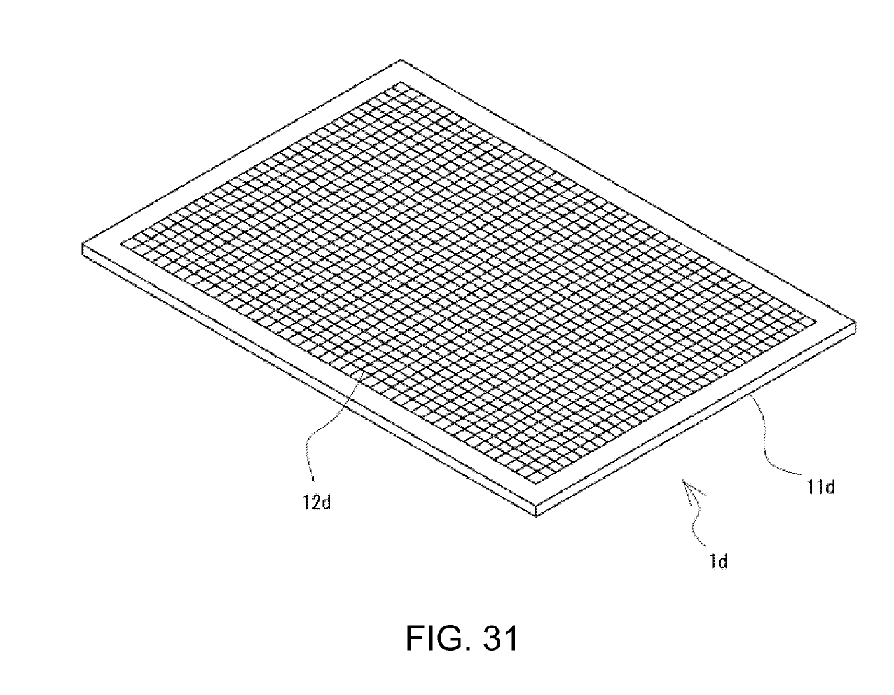

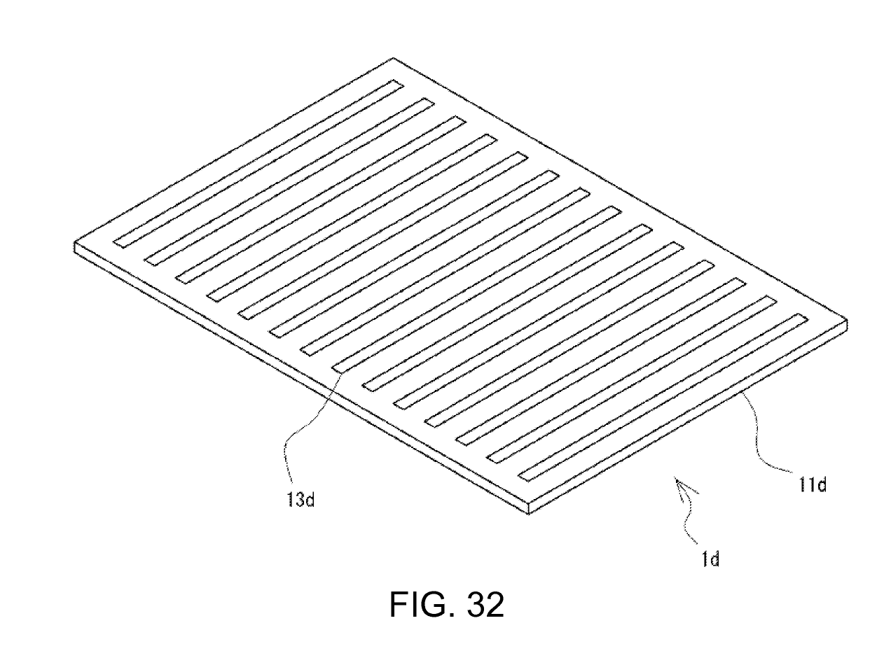

FIG. 31 is an exterior perspective view schematically showing the configuration of the exposure mask 1d of Embodiment 4 of the present invention. It is also an exterior perspective view showing the surface on one side with respect to the direction of the thickness and illustrating the surface on which the first semi-transmissive pattern 12d is formed. FIG. 32 is an exterior perspective view schematically showing the configuration of the exposure mask 1d of Embodiment 4 of the present invention. It is also an exterior perspective view showing the surface on the other side with respect to the direction of the thickness (the surface opposite to the surface shown in FIG. 31) and illustrating the surface on which the second semi-transmissive pattern 13d is formed.

As shown in FIG. 31 and FIG. 32, the exposure mask 1d of Embodiment 4 of the present invention has a transparent substrate 11d (i.e., a substrate that can transmit the light energy of the first wavelength band and the light energy of the second wavelength band that are delivered by the exposure device). Also, a first semi-transmissive pattern 12d is formed on the surface of the transparent substrate 11d on one side with respect to the direction of the thickness, and a second semi-transmissive pattern 13d is formed on the surface on the other side. An alternative configuration is that both the first semi-transmissive pattern 12d and the second semi-transmissive pattern 13d are formed on a single surface of the transparent substrate 11d.

In a manner similar to the first semi-transmissive pattern 12b of the exposure mask 1b of Embodiment 2 of the present invention, the first semi-transmissive pattern 12d of the exposure mask 1d of Embodiment 4 of the present invention can block the light energy of the first wavelength band and can transmit the light energy of the second wavelength band. In a manner similar to the second semi-transmissive pattern 13b of the exposure mask 1b of Embodiment 2 of the present invention, the second semi-transmissive pattern 13d of the exposure mask 1d of Embodiment 4 of the present invention can block the light energy of the second wavelength band and can transmit the light energy of the first wavelength band.

If the light energy of the first wavelength band delivered by the exposure device is the light energy of a short wavelength band (i.e., light energy of blue wavelength band) and if the light energy of the second wavelength band is the light energy of a long wavelength band (i.e., light energy of a red wavelength band), for example, the first semi-transmissive pattern 12d of the exposure mask 1d of Embodiment 4 of the present invention is made of a material containing a blue pigment and the second semi-transmissive pattern 13d is made of a material containing a red pigment. With such a configuration, if the light energy of a short wavelength is used as the light energy of the first wavelength band, the light energy of the first wavelength band cannot pass through the first semi-transmissive pattern 12d, but can pass through the second semi-transmissive pattern 13d. Also, if the light energy of a long wavelength is employed as the light energy of the second wavelength band, the light energy of the second wavelength band cannot pass through the second semi-transmissive pattern 13d, but can pass through the first semi-transmissive pattern 12d.

The first semi-transmissive pattern 12d of the exposure mask 1d of Embodiment 4 of the present invention is a pattern for forming the black matrix 62. As shown in FIG. 31, the first semi-transmissive pattern 12d is formed into the dimensions and the shape corresponding to the dimensions and the shape of the black matrix 62 (approximately the same dimensions and the shape as the black matrix 62).

The second semi-transmissive pattern 13d of the exposure mask 1d of Embodiment 4 of the present invention is a pattern for forming the colored layers 63r, 63g, and 63b of respective colors. As shown in FIG. 32, the second semi-transmissive pattern 13d is formed into the dimensions and the shape corresponding to the dimensions and the shape of the colored layers 63r, 63g, and 63b of respective colors (approximately the same dimensions and the shape as the colored layers 63r, 63g, and 63b of respective colors). Specifically, it is a pattern of long, thin strips extending along one of the directions of the matrix arrangement of pixels (the row direction or the column direction). The long, thin strips of the pattern are disposed with prescribed intervals (specifically, intervals equivalent to three pitches of the pixel arrangement) in between and are arranged approximately in parallel with each other.

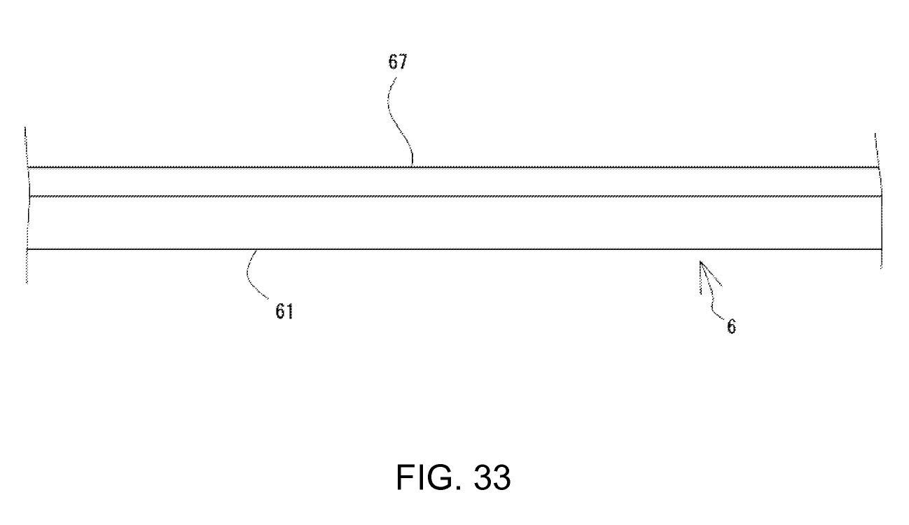

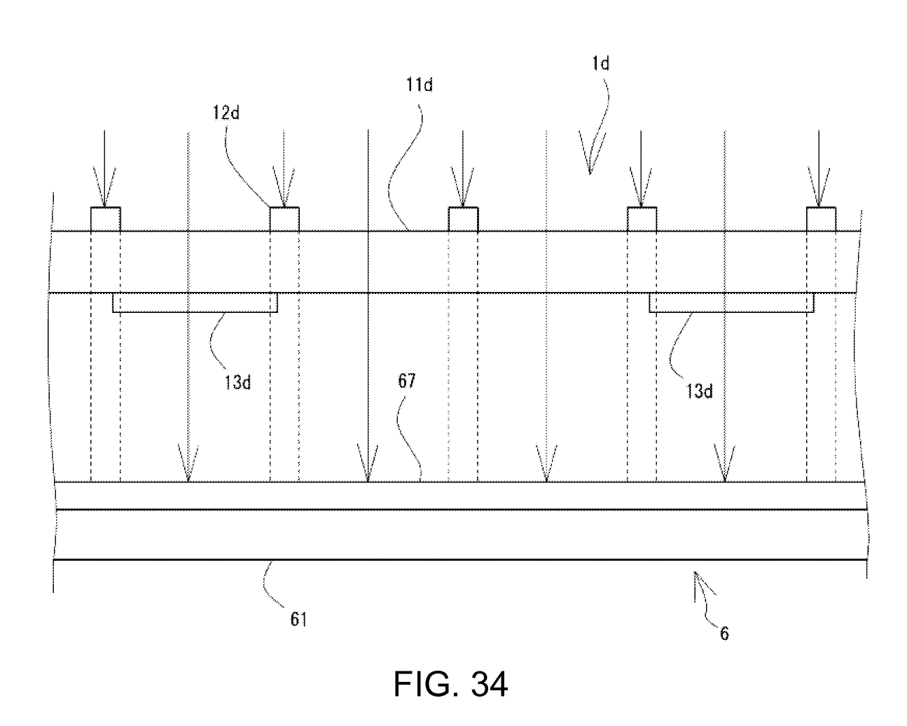

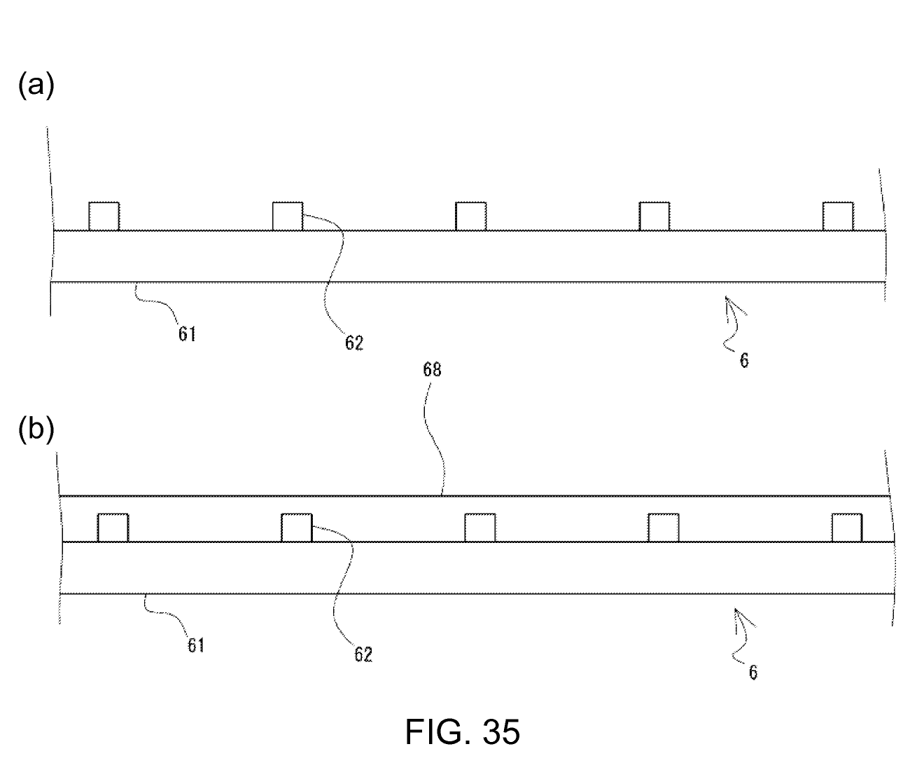

The step of forming a black matrix is as follows. FIG. 33, FIG. 34, and FIG. 35(a) are cross-sectional views schematically showing the step of forming a black matrix. Specifically, FIG. 33 shows the step of forming a BM resist film 67 on a surface of the transparent substrate 61. FIG. 34 shows the step of conducting an exposure process on the thus formed BM resist film 67. FIG. 35(a) shows the step of conducting a development process on the BM resist film 67, which has gone through the exposure process. FIG. 33, FIG. 34, and FIG. 35(a) show a portion of the substrate 6 of Embodiment 3 of the present invention.

First, as shown in FIG. 33, on the surface of the transparent substrate 61, a BM resist film 67 (a composite material for the black matrix 62, which is a photosensitive resin composite containing black colorant) is formed. The BM resist film 67 is made of a photoresist material whose solubility in developer changes by being irradiated with the light energy of the first wavelength band. The BM resist film 67 may be formed with a method using a spin coater or the like, for example.

Next, the BM resist film 67 which is now formed is patterned into a prescribed pattern. For the patterning of the BM resist film 67, a photolithography method according to an embodiment of the present invention is employed.

Specifically, as shown in FIG. 34, an exposure process is conducted on the formed BM resist film 67 using the exposure mask 1d of Embodiment 4 of the present invention. The arrows in the figure schematically indicate the light energy. That is, the exposure mask 1d of Embodiment 4 of the present invention is placed over the surface of the BM resist film 67, and through the exposure mask 1d of Embodiment 4 of the present invention, the BM resist film 67 is irradiated with the light energy of the first wavelength band delivered by an exposure device.

When the exposure device delivers the light energy of the first wavelength band, a portion of the light energy of the first wavelength band is blocked by the first semi-transmissive pattern 12d of the exposure mask 1d of Embodiment 4 of the present invention, and the remaining light energy passes through the exposure mask 1d of Embodiment 4 of the present invention. Because the light energy of the first wavelength band can pass through the second semi-transmissive pattern 13d, the second semi-transmissive pattern 13d does not become a barrier to the passage of the light energy of the first wavelength band through the exposure mask 1d of Embodiment 4 of the present invention. As a result, the portion of the BM resist film 67 over which the first semi-transmissive pattern 12d (i.e., the pattern having approximately the same dimensions and shape as the black matrix 62) is projected is not irradiated with the light energy of the first wavelength band, and the remaining portion is irradiated with the light energy of the first wavelength band regardless of the presence of the second semi-transmissive pattern 13d.

Next, as shown in FIG. 35(a), a development process is conducted on the BM resist film 67 that went through the exposure process. Once the development process is conducted, the portion of the BM resist film 67 that was irradiated with the light energy of the first wavelength band in the exposure process is removed. As a result, a black matrix 62 having a prescribed shape is obtained.

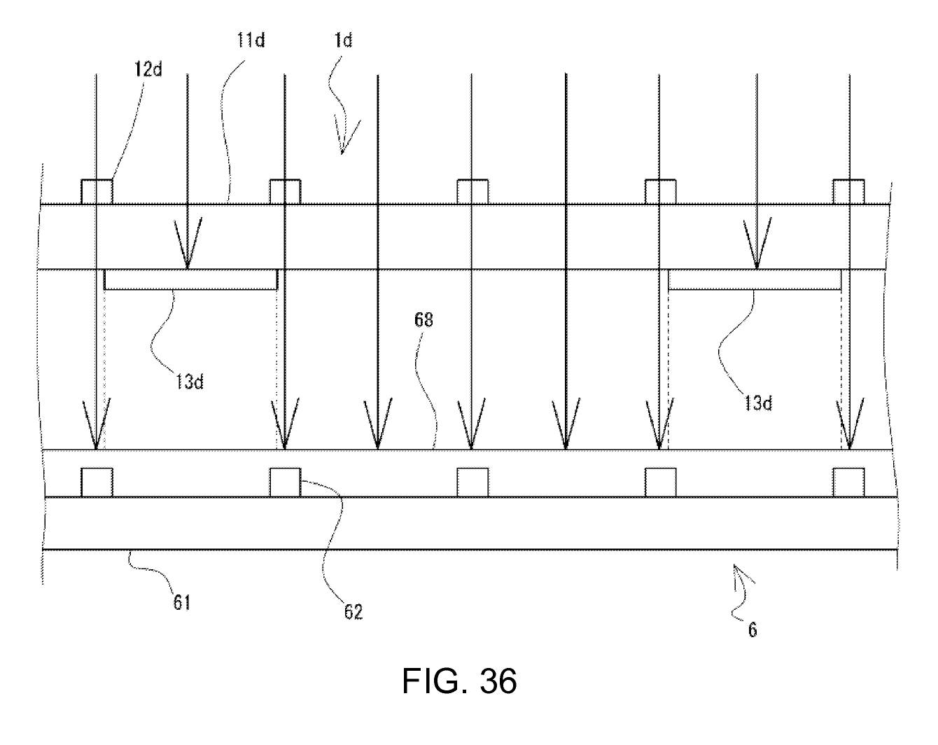

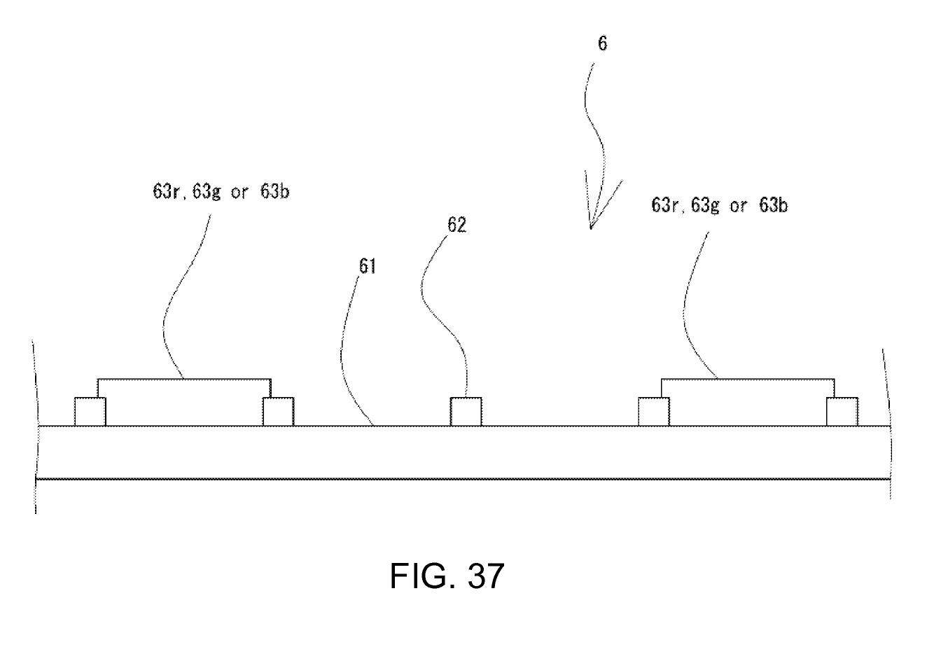

In the step of forming the colored layers, colored layers 63r, 63g, and 63b for color display, which are red, green, and blue, respectively, are formed. The step, in the case of the colored photosensitive material method, for example, is as follows. FIG. 35(b), FIG. 36, and FIG. 37 are cross-sectional views schematically showing the step of forming the colored layers of respective colors. Specifically, FIG. 35(b) shows the step of forming a film 68 of the colored photosensitive material of a prescribed color (red, green, or blue) on one surface of the transparent substrate 61. FIG. 36 shows the step of conducting an exposure process on the colored photosensitive material film 68 which is now formed. FIG. 37 shows the step of conducting a development process on the colored photosensitive material film 68 that went through the exposure process.

First, as shown in FIG. 35(b), over the surface of the transparent substrate 61 on which the black matrix 62 was formed, a colored photosensitive material of a prescribed color (red, green, or blue), i.e., a solution of a photosensitive material dispersed with a pigment or dye of the prescribed color, is applied to form a colored photosensitive material film 68. As the colored photosensitive materials of respective colors, a photoresist material whose solubility in developer changes by being irradiated with the light energy of the second wavelength band is used. Here, a positive type photoresist material is used.

Then, as shown in FIG. 36, an exposure process is conducted on the colored photosensitive material film 68 using the exposure mask 1d of Embodiment 4 of the present invention. The arrows in the figure schematically indicate the light energy. That is, the exposure mask 1d of Embodiment 4 of the present invention is placed over the surface of the colored photosensitive material film 68, and through the exposure mask 1d of Embodiment 4 of the present invention, prescribed portions of the colored photosensitive material film 68 are irradiated with the light energy of the second wavelength band delivered by an exposure device.

The exposure mask 1d of Embodiment 4 of the present invention is positioned such that the second semi-transmissive patterns 13d are projected over the prescribed grids (i.e., pixels) defined by the black matrix 62. As described above, the second semi-transmissive pattern 13d is a pattern of long, thin strips extending along one of the directions of the matrix arrangement of pixels (the row direction or the column direction). On the exposure mask 1d of Embodiment 4 of the present invention, the second semi-transmissive pattern 13d, which is a pattern of long, thin strips, is disposed with prescribed intervals (specifically, intervals equivalent to three pitches of the pixel arrangement) between the strips and the strips are arranged approximately in parallel with each other. Consequently, the exposure mask 1d of Embodiment 4 of the present invention is positioned such that the strips of the second semi-transmissive pattern 13d are projected over ⅓ of all the columns of grids defined by the black matrix 62. That is, the exposure mask 1d is positioned such that a strip of the second semi-transmissive pattern 13d is projected over every third column of grids.

When the exposure device delivers the light energy of the second wavelength band, a portion of the light energy of the second wavelength band is blocked by the second semi-transmissive pattern 13d of the exposure mask 1d of Embodiment 4 of the present invention, and the remaining portion passes through the exposure mask 1d of Embodiment 4 of the present invention. Because the light energy of the second wavelength band can pass through the first semi-transmissive pattern 12d, the first semi-transmissive pattern 12d does not become a barrier to the passage of the light energy of the second wavelength band through the exposure mask 1d of Embodiment 4 of the present invention. As a result, the portion of the colored photosensitive material film 68 over which the second semi-transmissive pattern 13d is projected is not irradiated with the light energy of the second wavelength band, and the remaining portion is irradiated with the light energy of the second wavelength band regardless of the presence of the first semi-transmissive pattern 12d.

That is, of the columns of grids defined by the black matrix 62 (colored photosensitive material films 68 formed in those columns of grids), prescribed ⅓ of the columns of grids (colored photosensitive material films 68 formed in those columns of grids) are not irradiated with the light energy of the second wavelength band, and other columns of grids (colored photosensitive material film 68 formed in those columns of grids) are irradiated with the light energy of the second wavelength band.

Next, as shown in FIG. 37, a development process is conducted on the colored photosensitive material film 68 of the prescribed color that has gone through the exposure process. Once the development process is conducted, of the colored photosensitive material film 68 of the prescribed color, the portion irradiated with the light energy of the second wavelength band in the exposure process is removed, and the portion that was not irradiated is preserved. Consequently, for the prescribed ⅓ among all the columns of grids defined by the black matrix 62, the colored photosensitive material film 68 of prescribed color is preserved, and this becomes a colored layer 63r, 63g, or 63b of the prescribed color.

This process is conducted for each of the red colored layer 63r, the green colored layer 63g, and the blue colored layer 63b. As a result, colored layers 63r, 63g, and 63b of respective colors are obtained. For the formation of the red colored layer 63r, green colored layer 63g, and blue colored layer 63b, a single exposure mask 1d of Embodiment 4 of the present invention is used. That is, for each of the steps of forming the red colored layer 63r, the green colored layer 63g, and the blue colored layer 63b, the exposure mask 1d of Embodiment 4 of the present invention can be moved to a different corresponding position. That is, the exposure mask 1d of Embodiment 4 of the present invention is positioned such that the second semi-transmissive pattern 13d is projected over the columns of pixels for which the prescribed color of colored layer 63r, 63g, or 63b is to be formed. With such a method, all colored layers 63r, 63g, and 63b having respective colors are formed using a single exposure mask 1d of Embodiment 4 of the present invention.

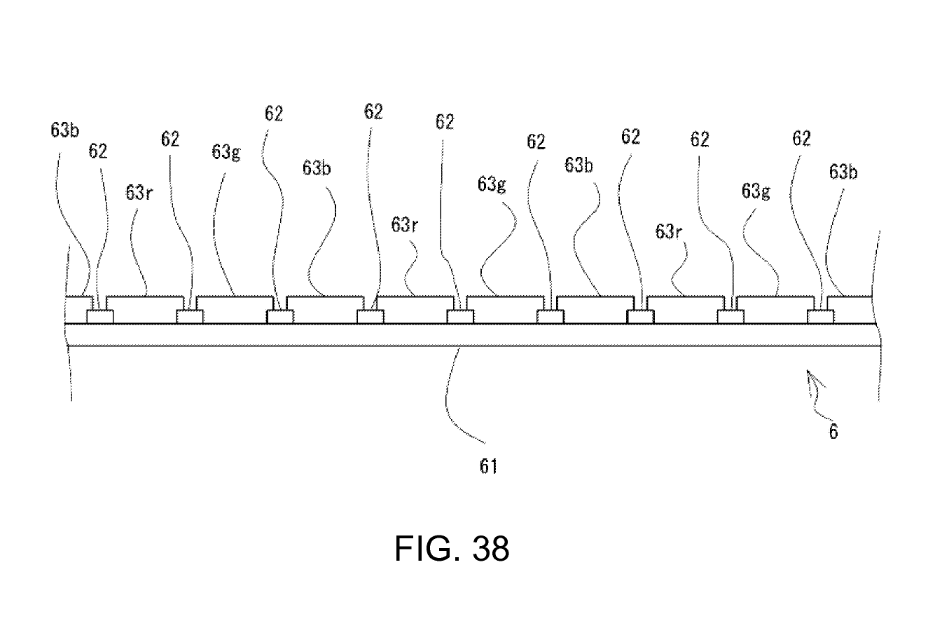

FIG. 38 schematically shows the cross-sectional structure of the transparent substrate 61 on which colored layers 63r, 63g, and 63b of respective colors are formed (semi-finished substrate 6 of Embodiment 3 of the present invention). As shown in FIG. 38, in the grids (i.e., pixels) defined by the black matrix 62, colored layers 63r, 63g, and 63b of respective colors are formed. Specifically, on the surface of the transparent substrate 61, columns of pixels for which red colored layer 63r is to be formed, columns of pixels for which green colored layer 63g is to be formed, and columns of pixels for which blue colored layer 63b is to be formed are arranged periodically.

In the step of forming a protective film, a protective film 65 is formed on the surfaces of the black matrix 62 and the colored layers 63r, 63g, and 63b. The protective film 65 may be formed, for example, by applying a protective film material over the surface of the transparent substrate 61 that went through the step described above using a spin coater (entire surface application method), or by forming the protective film 65 of a prescribed pattern with the printing, photolithography, or like method (patterning method). As the protective film material, acrylic resin or epoxy resin, for example, may be used.

In the process of forming a transparent electrode (common electrode) film, a transparent electrode (common electrode) 64 is formed on the surface of the protective film 65. In the case of a masking method, for example, a mask is placed on the surface of the transparent substrate 61 that went through the step described above, and indium tin oxide (ITO) or the like is vapor-deposited by sputtering or the like to form the transparent electrode (common electrode) 64.

Next, alignment control structures 66 are formed. The alignment control structures 66 are made of a photosensitive resin material or the like, for example, and are formed with the photolithography method or the like. A photosensitive material film is formed on the surface of the transparent substrate 61 that went through the above-mentioned step (i.e., the surface of the transparent electrode (common electrode) 64), and an exposure process is conducted on the surface using the exposure mask having a prescribed light-transmissive pattern and a light-shielding pattern. Then, unnecessary portions are removed in the step of development, and alignment control structures 66 of a prescribed pattern is obtained.

Through these steps, the substrate 6 of Embodiment 3 of the present invention can be obtained.

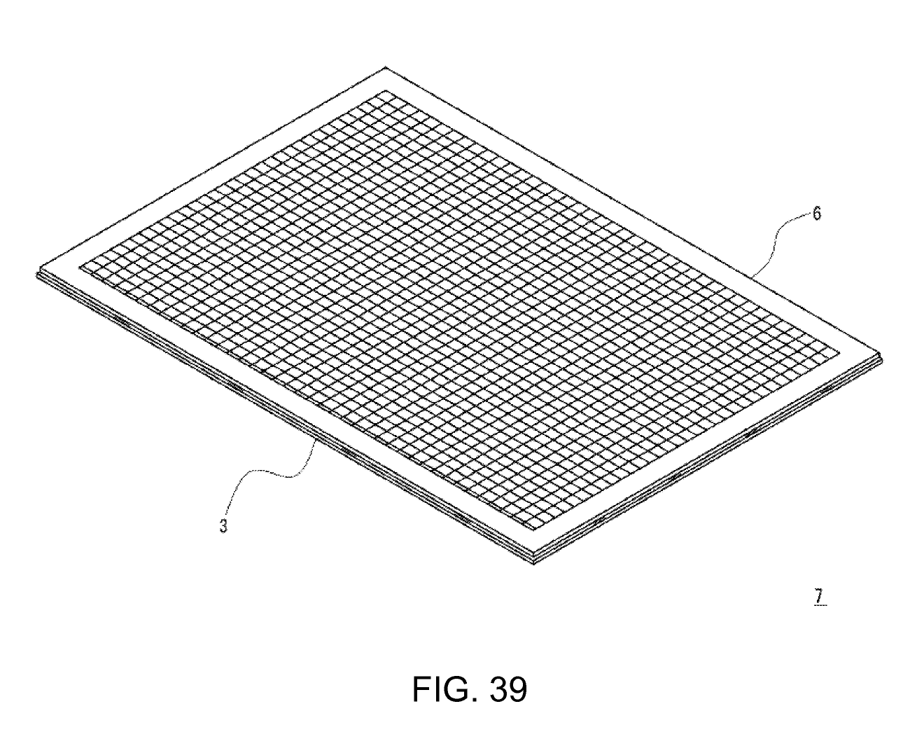

Next, the display panel employing the substrate 3 of Embodiment 2 of the present invention and the substrate 6 of Embodiment 3 of the present invention (hereinafter referred to as “display panel 7 according to an embodiment of the present invention”) is described. FIG. 39 is an exterior perspective view showing the configuration of the display panel 7 according to an embodiment of the present invention.

The display panel 7 according to an embodiment of the present invention is an active matrix type liquid crystal display panel. The display panel 7 according to an embodiment of the present invention has the substrate 3 of Embodiment 2 of the present invention and the substrate 6 of Embodiment 3 of the present invention. The substrate 3 of Embodiment 2 of the present invention and the substrate 6 of Embodiment 3 of the present invention are bonded together with a sealing member face-to-face, with a prescribed space in between. The space between the substrate 3 of Embodiment 2 of the present invention and the substrate 6 of Embodiment 3 of the present invention is filled with liquid crystal, which is sealed in by the sealing member.

The method of manufacturing the display panel 7 according to an embodiment of the present invention is briefly explained. The method of manufacturing the display panel 7 according to an embodiment of the present invention includes the step of manufacturing the TFT array substrate, the step of manufacturing the color filter, and the step of manufacturing the panel (also referred to as “step of manufacturing the cell”). The step of manufacturing the TFT array substrate is the step of manufacturing the substrate 3 of Embodiment 2 of the present invention, which has been already described. The step of manufacturing the color filter is the step of manufacturing the substrate 6 of Embodiment 3 of the present invention, which has been already described.

The step of manufacturing the panel (also referred to as “step for manufacturing the cell”) is as follows.

First, an alignment film is formed on the substrate 3 of Embodiment 2 of the present invention and on the substrate 6 of Embodiment 3 of the present invention. The method of forming the alignment film on the surfaces of the substrate 3 of Embodiment 2 of the present invention and on the substrate 6 of Embodiment 3 of the present invention is as follows.

First, using an alignment material application device or the like, an alignment material is applied on the surfaces of the active regions of the substrate 3 of Embodiment 2 of the present invention and of the substrate 6 of Embodiment 3 of the present invention. The alignment material refers to a solution containing the material for the alignment film. As the alignment material application device, an inkjet system printing device (dispenser) can be used.

The alignment material applied is heated by an alignment film burning device or the like and is baked. Then, an alignment process is conducted on the baked alignment film. The alignment process can be conducted in various known methods. For example, the surface of the alignment film may be finely scratched using a rubbing roll, or the optical alignment process may be conducted, in which the surface of the alignment film is irradiated with the light energy such as the ultraviolet ray to adjust the condition of the surface of the alignment film. The alignment process, however, may be omitted.

Next, using a seal patterning device or the like, a sealing material is applied over the seal pattern region 332 of the substrate 3 of Embodiment 2 of the present invention. For the sealing member application, various known seal dispensers may be used.

Then, using a spacer dispersion device or the like, spacers for maintaining the cell gap to a prescribed value (plastic beads having a prescribed diameter, for example) are dispersed over the surface of the substrate 3 of Embodiment 2 of the present invention. It should be noted that in a configuration where column-shaped spacers are formed on the substrate 6 of Embodiment 3 of the present invention, spacers are not dispersed. Next, using a liquid crystal dripping device or the like, liquid crystal is dripped onto the region bordered by the sealing member on the surface of the substrate 3 of Embodiment 2 of the present invention.

Next, under a reduced-pressure atmosphere, the substrate 3 of Embodiment 2 of the present invention and the substrate 6 of Embodiment 3 of the present invention are bonded together. The sealing member is then cured. If a sealing member curable by the ultraviolet ray is used, the sealing member is irradiated with the ultraviolet ray after the bonding. Alternatively, liquid crystals can be introduced between the substrate 3 of Embodiment 2 of the present invention and the substrate 6 of Embodiment 3 of the present invention after the sealing member is cured.

Through these steps, the display panel 7 according to an embodiment of the present invention is obtained.

With such a configuration, a similar operational effect as the one provided by the exposure mask 1a of Embodiment 1 of the present invention and the photolithography method can be obtained.

The photoresist material used in embodiments of the present invention does not need to be responsive only to the light energy of a prescribed wavelength band, but may be responsive to the light energy of all the wavelength bands (both the light energy of the first wavelength band and the light energy of the second wavelength band, for example). For this reason, various general photoresist materials can be used for embodiments of the present invention.

When the wavelength band of the light energy delivered by an exposure device changes, the so-called “amount of energy” that the light energy has (light intensity, in other words) changes. As a result, if the wavelength band of the light energy changes, by adjusting the duration of the light energy irradiation, the total amount of “energy” to be given to the photoresist material can be adjusted.

### INDUSTRIAL APPLICABILITY

Embodiments of the present invention are described in detail above. The present invention, however, is not limited to the aforementioned embodiments in any way, and various changes can be made within the spirit of the present invention.

For example, in the description of the method of manufacturing the substrate 3 of Embodiment 2 of the present invention, a single common exposure mask (the exposure mask 1b of Embodiment 2 of the present invention) is used to form the gate wirings 41, the reference wirings 50, the gate electrodes 441 of the thin film transistors 44, and the semiconductor film 46, and a single common exposure mask (the exposure mask 1c of Embodiment 3 of the present invention) is used to form the source wirings 42, the drain wirings 43, the source electrodes 442 and drain electrodes 443 of the thin film transistors 44, and the organic insulating film 48. However, a single mask may be used to form all of these wirings and elements. That is, four types of semi-transmissive patterns may be formed using a single mask. In this case, the semi-transmissive patterns just need to block the light energies of respective wavelength bands, which are all mutually different, and transmit the light energy of other wavelength bands.

Thus, the type and the number of the semi-transmissive patterns formed on the exposure mask according to embodiments of the present invention are not limited.

In the description above, configurations where the exposure masks 1a, 1b, 1c, and 1d according to embodiments of the present invention are positive type exposure masks and a positive type photoresist material is employed are discussed. However, whether the exposure mask is positive or negative, and whether the photoresist material is positive or negative are not limited in any way. That is, the present invention is also applicable to configurations where a negative exposure mask and a negative photoresist material are used. In this case, the region of the exposure mask where the first semi-transmissive pattern is formed and the region where the first semi-transmissive pattern is not formed only need to be switched. Similarly, the region where the second semi-transmissive pattern is formed and the region where the second semi-transmissive pattern is not formed only need to be switched.

1: An exposure mask comprising:
a substantially transparent substrate; and
multiple semi-transmissive patterns formed on said substantially transparent substrate, each of which semi-transmissive patterns can block, among multiple types of light energy of different wavelength bands, light energy of a prescribed wavelength band and can transmit light energy of other wavelength bands,
wherein said multiple types of semi-transmissive patterns block light energy of respective wavelength bands that are different from one another.

2: The exposure mask according to claim 1, wherein said multiple semi-transmissive patterns are formed into different dimensions and shapes.

3: An exposure mask comprising:
a substantially transparent substrate; and
N (N is an integer of at least 2) semi-transmissive patterns formed on said substantially transparent substrate, each of which semi-transmissive patterns can block, among N light energies of different wavelength bands, light energy of a prescribed wavelength and can transmit light energy of other wavelength bands,
wherein said N semi-transmissive patterns block light energies of respective wavelength bands that are different from one another.

4: The exposure mask according to claim 3, wherein said N semi-transmissive patterns are formed into different dimensions and shapes.

5. An exposure mask comprising:
a substantially transparent substrate;
a first semi-transmissive pattern formed on said substantially transparent substrate, the first semi-transmissive pattern blocking light energy of a first wavelength band, and transmitting light energy of a second wavelength band that is different from said first wavelength band; and
a second semi-transmissive pattern formed on said substantially transparent substrate, the semi-transmissive pattern blocking the light energy of said second wavelength band, and transmitting the light energy of said first wavelength band.

6: The exposure mask according to claim 5, wherein said first semi-transmissive pattern is formed on a surface of said substantially transparent substrate on one side, and said second semi-transmissive pattern is formed on a surface of said substantially transparent substrate on the other side.

7: The exposure mask according to claim 5, wherein said exposure mask is for forming multiple prescribed elements on a surface of a substrate, and
wherein said first semi-transmissive pattern and said second semi-transmissive pattern are formed into dimensions and shapes corresponding to dimensions and shapes of mutually different prescribed elements among said multiple prescribed elements.

8: The exposure mask according to claim 7,
wherein said substrate is a TFT array substrate for an active matrix type liquid crystal display panel that includes, as said prescribed elements, gate wirings, source wirings, a semiconductor film, reference wirings, thin film transistors, and an organic insulating film, and
wherein said first semi-transmissive pattern and said second semi-transmissive pattern are formed into dimensions and shapes corresponding to dimensions and shapes of one of: said gate wirings and gate electrodes of said thin film transistors; said source wirings, said drain wirings, source electrodes of said thin film transistors, and drain electrodes of said thin film transistors; said organic insulating film; and said semiconductor film.

9: The exposure mask according to claim 7,
wherein said substrate is a color filter for an active matrix type liquid crystal display panel including, as said prescribed elements, a black matrix and a colored layer of prescribed color,
wherein one of said first semi-transmissive pattern and said second semi-transmissive pattern is formed into dimensions and a shape corresponding to dimensions and shape of said black matrix, and
wherein the other of said first semi-transmissive pattern and said second semi-transmissive pattern is formed into dimensions and a shape corresponding to dimensions and shape of said colored layer.

10: A photolithography method using the exposure mask according to claim 1, comprising the steps of:
forming a photoresist material film;
conducting an exposure process on said photoresist material film using the exposure mask according to claim 1 and light energy of a certain wavelength band;
conducting a development process on said photoresist material film that went through the exposure process;
forming another photoresist material film;
conducting an exposure process on said another photoresist material film using said exposure mask according to claim 1 and light energy of another wavelength band that is different from said certain wavelength band; and
conducting a development process on said another photoresist material film that went through the exposure process.

11: The photolithography method according to claim 10, wherein said photoresist material film is a photoresist material film whose solubility in developer changes by being irradiated with the light energy of said certain wavelength band, and said another photoresist material film is a photoresist material film whose solubility in developer changes by being irradiated with the light energy of said another wavelength band.

12: A photolithography method using the exposure mask according to claim 3, comprising the steps of:
forming a photoresist material film;
conducting an exposure process on said photoresist material film using the exposure mask according to claim 3 and using light energy of a prescribed wavelength band among light energy of N different wavelength bands;
conducting a development process on said photoresist material film that went through the exposure process;
forming another photoresist material film;
conducting an exposure process on said another photoresist material film using said exposure mask according to claim 3 and using light energy of another prescribed wavelength band among the light energy of the N different wavelength bands; and
conducting a development process on said another photoresist material film that went through the exposure process.

13: The photolithography method according to claim 12, wherein said photoresist material film is a photoresist material film whose solubility in developer changes by being irradiated with the light energy of said prescribed wavelength band, and said another photoresist material film is a photoresist material film whose solubility in developer changes by being irradiated with the light energy of said another prescribed wavelength band.

14: A photolithography method using the exposure mask according to claim 5, comprising the steps of:
forming a photoresist material film;
conducting an exposure process on said photoresist material film using said exposure mask according to claim 5 with light energy of said first wavelength band;
conducting a development process on said photoresist material film that went through the exposure process;
forming another photoresist material film;
conducting an exposure process on said another photoresist material film using said exposure mask according to claim 5 with light energy of said second wavelength band; and
conducting a development process on said another photoresist material film that went through the exposure process.

15: The photolithography method according to claim 14,
wherein said photoresist material film is a photoresist material film whose solubility in developer changes by being irradiated with the light energy of said first wavelength band; and
wherein said another photoresist material film is a photoresist material film whose solubility in developer changes by being irradiated with the light energy of said second wavelength band.

16: A photolithography method using the exposure mask according to claim 8, comprising the steps of:
forming, on a surface of said substrate, one of: a film that is a material for said gate wirings and said gate electrodes of said thin film transistors; a film that is a material for said source wirings, said drain wirings, said source electrodes of said thin film transistors, and said drain electrodes of said thin film transistors; a film that is a material for said organic insulating film; and a film that is a material for said semiconductor film;
forming a photoresist material film on a surface of said film that has been formed;
conducting an exposure process on said photoresist material film using the exposure mask according to claim 8 and light energy of said first wavelength band;
conducting a development process on said photoresist material film that went through the exposure process;
patterning said film that has been formed, using said photoresist material film that has been developed as a mask to form one of: said gate wirings and said gate electrodes of said thin film transistors; said source wirings, said drain wirings, said source electrodes of said thin film transistors, and said drain electrodes of said thin film transistors; said organic insulating film; and said semiconductor film;
forming, on a surface of said substrate, another one of: the film that is the material for said gate wirings and said gate electrodes of said thin film transistors; the film that is the material for said source wirings, said drain wirings, said source electrodes of said thin film transistors, and said drain electrodes of said thin film transistors; the film that is the material for said organic insulating film; and the film that is the material for said semiconductor film;
forming another photoresist material film;
conducting an exposure process on said another photoresist material film using said exposure mask according to claim 8 and the light energy of said second wavelength band;
conducting a development process on said another photoresist material film that went through the exposure process;
patterning said film that has been formed, using said another photoresist material film that has been developed as a mask to form another one of: said gate wirings and said gate electrodes of said thin film transistors; said source wirings, said drain wiring, said source electrodes of said thin film transistors, and said drain electrodes of said thin film transistors; said organic insulating film; and said semiconductor film.

17: The photolithography method according to claim 16, wherein said photoresist material film is a photoresist material film whose solubility in developer changes by being irradiated with the light energy of said first wavelength band, and said another photoresist material film is a photoresist material film whose solubility in developer changes by being irradiated with the light energy of said second wavelength band.

18: A photolithography method using the exposure mask according to claim 9, comprising the steps of:
forming a photoresist material film that is a material for said black matrix on a surface of said substrate;
conducting an exposure process on said photoresist material film that is the material for said black matrix using the exposure mask according to claim 9 and light energy of the first wavelength band;
conducting a development process on said photoresist material film that went through the exposure process to form said black matrix;
forming a photoresist material film that is a material for said colored layer of prescribed color;
conducting an exposure process on said photoresist material film using said exposure mask according to claim 9 and light energy of said second wavelength band; and
conducting a development process on said photoresist material film, which is the material for said colored layer of prescribed color, that went through the exposure process to form said colored layer of prescribed color.

19: The photolithography method according to claim 18, wherein said photoresist material film is a photoresist material film whose solubility in developer changes by being irradiated with the light energy of said first wavelength band, and said another photoresist material film is a photoresist material film whose solubility in developer changes by being irradiated with the light energy of said second wavelength band.

20: A method of manufacturing a substrate, including the photolithography method according to claim 10.

21: A method of manufacturing a display panel, including the photolithography method according to claim 16.
